(19) United States
(12) Patent Application Publication
(10) Pub. No.: US 2025/0011342 A1
(43) Pub. Date: Jan. 9, 2025

(54) ORGANIC MOLECULES FOR OPTOELECTRONIC DEVICES

(71) Applicant: Samsung Display Co., Ltd., Yongin-si, Gyeonggi-do (KR)

(72) Inventor: Sebastian DÜCK, Heidelberg (DE)

(21) Appl. No.: 18/701,165

(22) PCT Filed: Oct. 13, 2022
(86) PCT No.: PCT/KR2022/015533

§ 371 Date: Apr. 12, 2024

(30) Foreign Application Priority Data
Oct. 15, 2021 (EP) 21203031.6

(51) Int. Cl. C07F 5/02; C09K 11/06; H10K 71/12; H10K 71/16; H10K 85/60

(52) U.S. Cl. CPC C07F 5/027; C09K 11/06; H10K 71/12; H10K 71/164; H10K 85/615; H10K 85/633; H10K 85/656; H10K 85/6572; H10K 85/658; C09K 2211/1096

(57) ABSTRACT

An organic molecule with a structure of Formula I is provided:

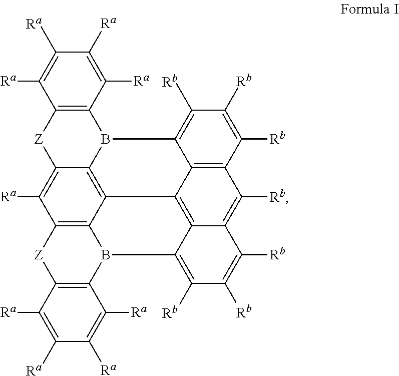

Z is independently selected from the group consisting of a direct bond, NR^{a}, O, and S; and
R^{a} and R^{b} is independently selected from the group consisting of: hydrogen, deuterium, N(R⁵)₂, OR⁵, Si(R⁵)₃, B(OR⁵)₂, B(R⁵)₂, OSO₂R⁵, CF₃, CN, F, Br, I, C₁-C₄₀-alkyl, C₁-C₄₀-alkoxy, C₁-C₄₀-thioalkoxy, C₂-C₄₀-alkenyl, C₂-C₄₀-alkynyl, C₆-C₆₀-aryl, and C₂-C₅₇-heteroaryl.

### CROSS-REFERENCE TO RELATED APPLICATION

The present application is a U.S. National Phase Patent Application of International Patent Application Number PCT/KR2022/015533, filed on Oct. 13, 2022, which claims priority to and the benefit of European Patent Application Number 21203031.6, filed on Oct. 15, 2021, the entire content of each of the two applications is incorporated herein by reference.

### TECHNICAL FIELD

The invention relates to light-emitting organic molecules and to oligomers including a plurality of such organic molecules as oligomer units and their use in organic light-emitting diodes (OLEDs) and in other optoelectronic devices.

### DISCLOSURE

### Technical Problem

The object of the present invention is to provide molecules which are suitable for use in optoelectronic devices.

### Technical Solution

This object is achieved by the invention which provides a new class of organic molecules.

According to the invention, the organic molecules are purely organic molecules, i.e., they do not contain any metal ions in contrast to metal complexes known for the use in optoelectronic devices. The organic molecules of the invention, however, include metalloids, in particular B, Si, Sn, Se, and/or Ge.

According to the present invention, the organic molecules exhibit emission maxima in the yellow, orange or red spectral range. The organic molecules exhibit in particular emission maxima between 570 nm and 800 nm, preferably between 580 nm and 700 nm, more preferably between 590 nm and 690 nm, and even more preferably between 610 nm and 665 nm. The photoluminescence quantum yields of the organic molecules according to the invention are, in particular, 30% or more. The use of the molecules according to the invention in an optoelectronic device, for example an organic light-emitting diode (OLED), leads to higher efficiencies or higher color purity, expressed by the full width at half maximum (FWHM) of emission, of the device. Corresponding OLEDs have a higher stability than OLEDs with known emitter materials and comparable color.

### Organic Molecules According to the Invention

The invention refers in a first aspect to organic molecules including or consisting of a structure of Formula I:

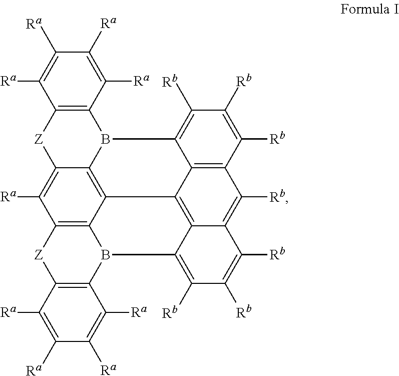

Z is at each occurrence independently from each other selected from the group consisting of a direct bond, NR^{a}, O, and S;
R^{a} and R^{b} are at each occurrence independently selected from the group consisting of: hydrogen; deuterium; N(R⁵)₂; OR⁵; Si(R⁵)₃; B(OR⁵)₂; B(R⁵)₂; OSO₂R⁵; CF₃; CN; F; Br, I;
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₂-C₅₇-heteroaryl,
which is optionally substituted with one or more substituents R⁵;
R⁵ is at each occurrence independently from each other selected from the group consisting of: hydrogen; deuterium; N(R⁶)₂; OR⁶; Si(R⁶)₃; B(OR⁶)₂; B(R⁶)₂; OSO₂R⁶; CF₃; CN; F; Br; I;
C₁-C₄₀-alkyl,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-alkoxy,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-thioalkoxy,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkenyl,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkynyl,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₆-C₆₀-aryl,
which is optionally substituted with one or more substituents R⁶; and
C₂-C₅₇-heteroaryl,
which is optionally substituted with one or more substituents R⁶;
R⁶ is at each occurrence independently from each other selected from the group consisting of: hydrogen; deuterium; OPh (Ph=phenyl); CF₃; CN; F;
C₁-C₅-alkyl,
wherein one or more hydrogen atoms are optionally, independently substituted by deuterium, CN, CF₃, or F;
C₁-C₅-alkoxy,
wherein one or more hydrogen atoms are optionally, independently substituted by deuterium, CN, CF₃, or F;
C₁-C₅-thioalkoxy,
wherein one or more hydrogen atoms are optionally, independently substituted by deuterium, CN, CF₃, or F;
C₂-C₅-alkenyl,
wherein one or more hydrogen atoms are optionally, independently substituted by deuterium, CN, CF₃, or F;
C₂-C₅-alkynyl,
wherein one or more hydrogen atoms are optionally, independently substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl);
wherein any of the substituents R^{a}, R^{b}, R⁵, and R⁶ may independently form a mono- or polycyclic, aliphatic, aromatic, heteroaromatic, and/or benzo-fused ring system with one or more other substituents R^{a}, R^{b}, R⁵ and/or R⁶.

In one embodiment, the organic molecules include or consist of a structure of Formula Ia, Formula Ib, or Formula Ic:

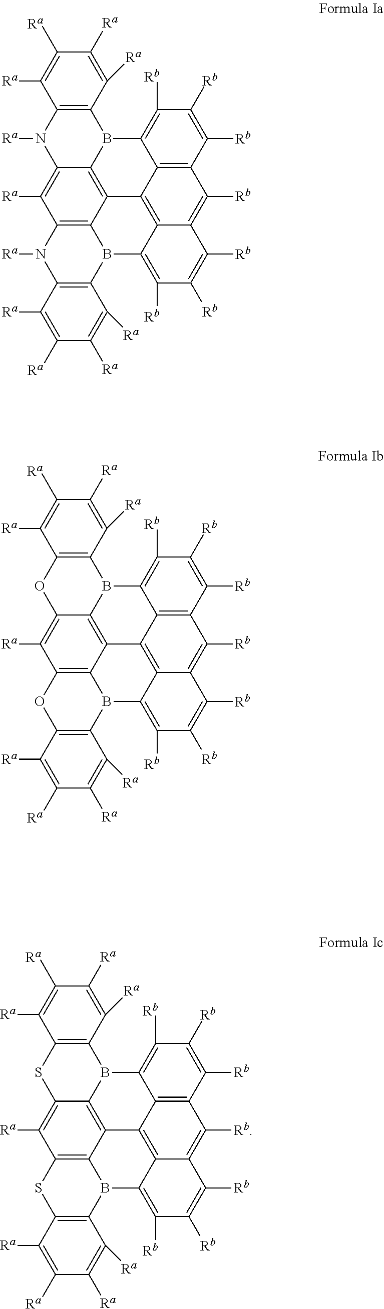

In one embodiment, the organic molecules include or consist of a structure of Formula Id, Formula Ie, or Formula If:

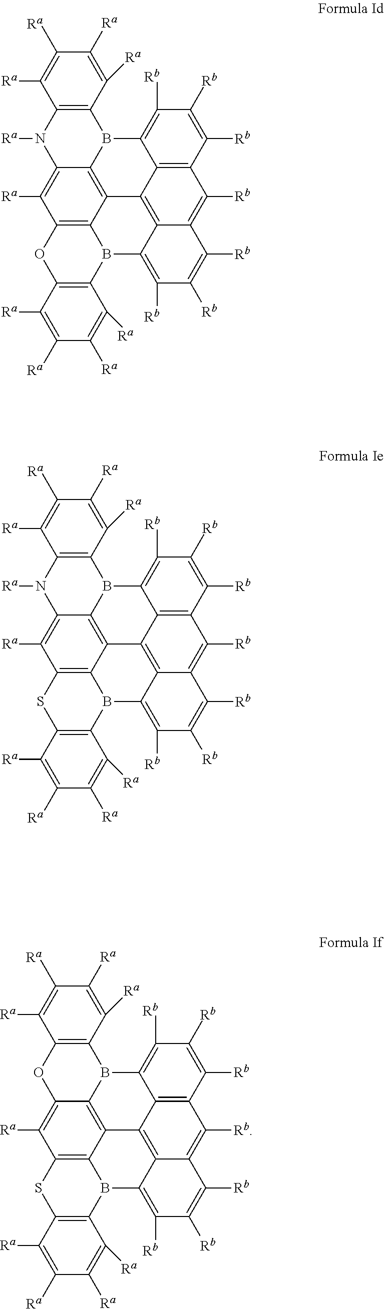

In a preferred embodiment, Z is at each occurrence independently from each other selected from the group consisting of NR^{a} and O.

In a preferred embodiment, the organic molecules include or consist of a structure of Formula II-1 or Formula II-2:

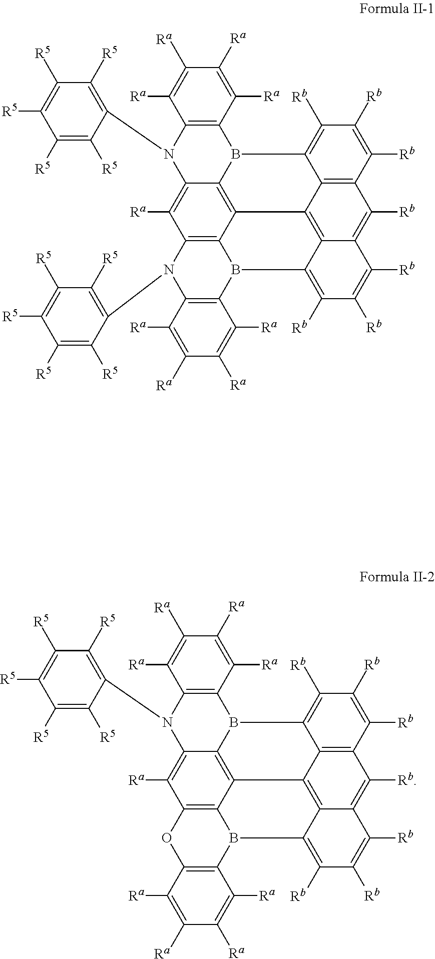

In one embodiment, the organic molecules include or consist of a structure of Formula IIa:

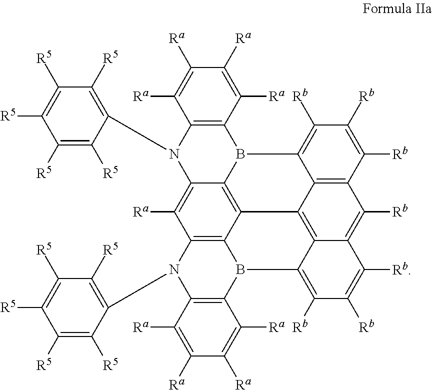

In one embodiment of the invention, Re is at each occurrence independently from each other selected from the group consisting of:
hydrogen,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃a, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In one embodiment of the invention, R⁵ is at each occurrence independently from each other selected from the group consisting of:
hydrogen,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In one embodiment, the organic molecules include or consist of a structure of Formula IIa-1:

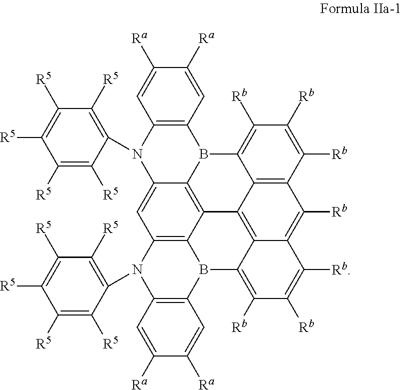

In one embodiment, the organic molecules include or consist of a structure of Formula IIa-2, Formula IIa-3, Formula IIa-4, or Formula IIa-5:

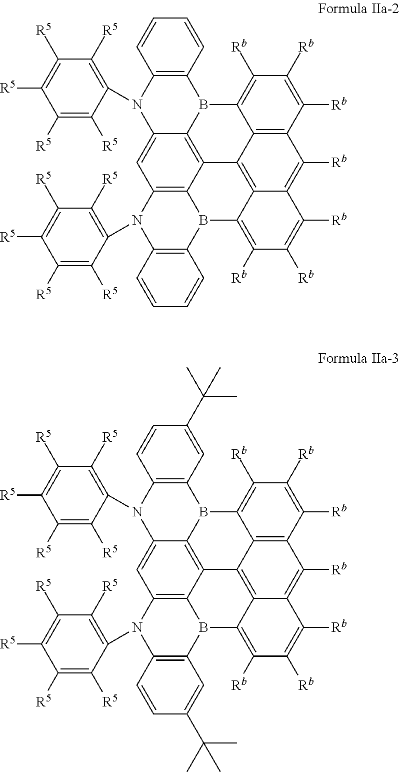

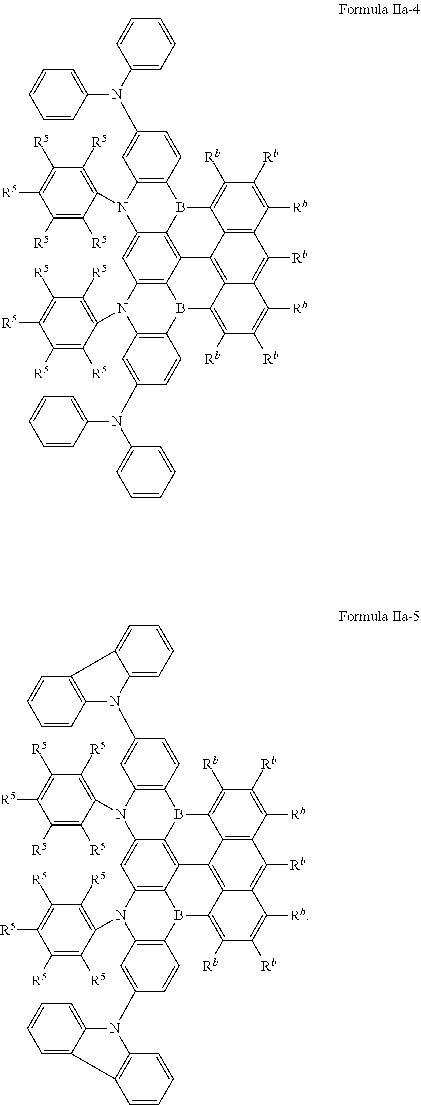

In one embodiment, the organic molecules include or consist of a structure of Formula IIa-1, wherein adjacent R^{a} substituents independently form a mono- or polycyclic, aliphatic, aromatic, heteroaromatic, and/or benzo-fused ring system.

In one embodiment, the organic molecules include or consist of a structure of Formula IIb-1, Formula IIb-2, Formula IIb-3, or Formula IIb-4:

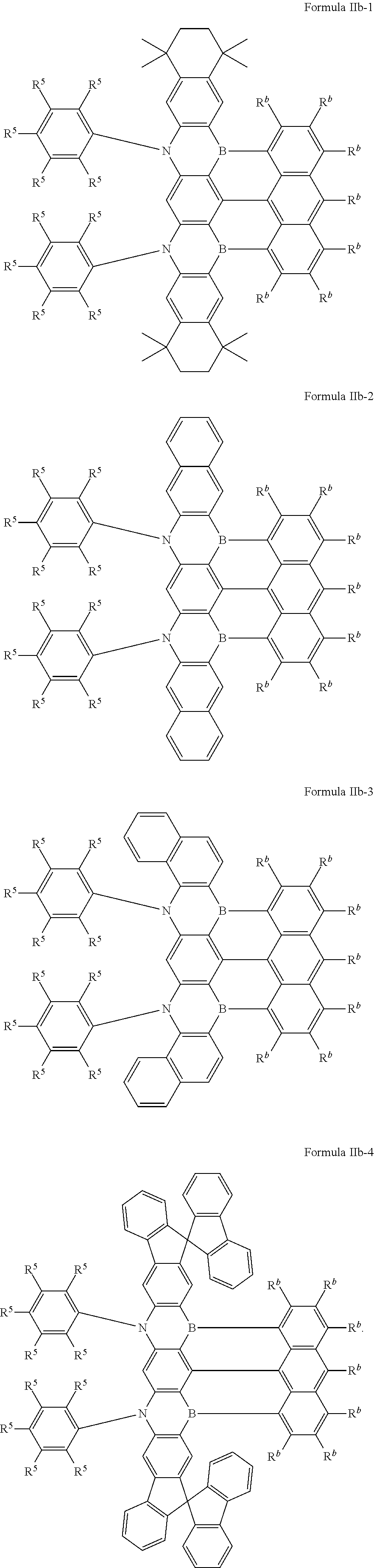

In one embodiment, the organic molecules include or consist of a structure of Formula III:

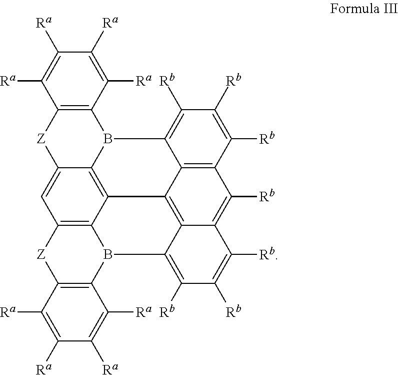

In one embodiment, the organic molecules include or consist of a structure of Formula IVa, Formula IVb, Formula IVc, Formula IVd, Formula IVe, or Formula IVf:

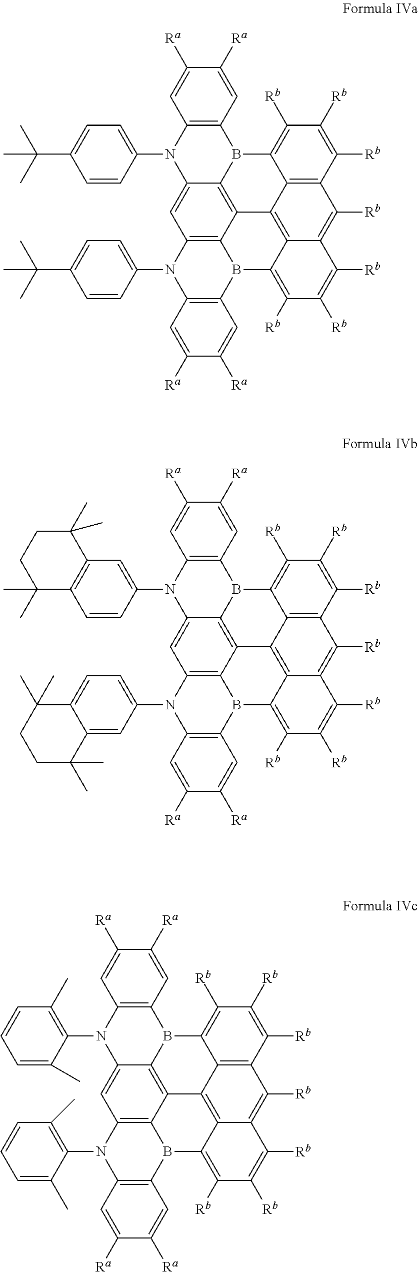

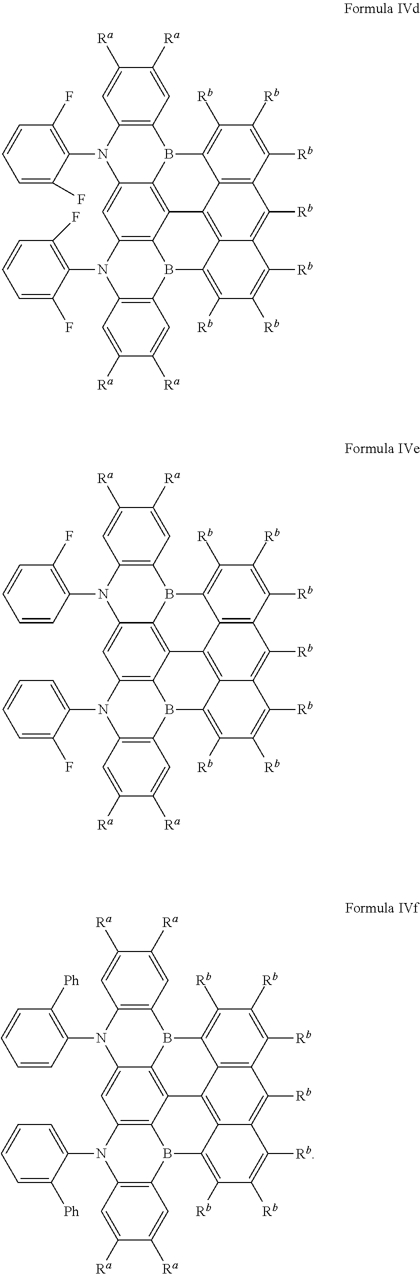

In one embodiment, the organic molecules include or consist of a structure of Formula V:

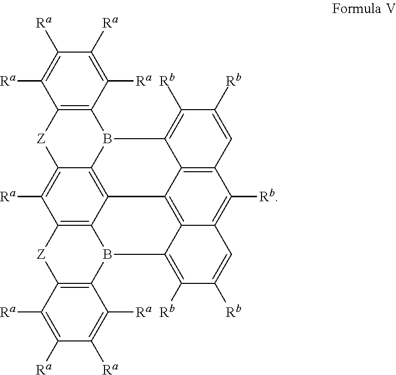

In one embodiment, the organic molecules include or consist of a structure of Formula V-1 Formula V-2 or Formula V-3:

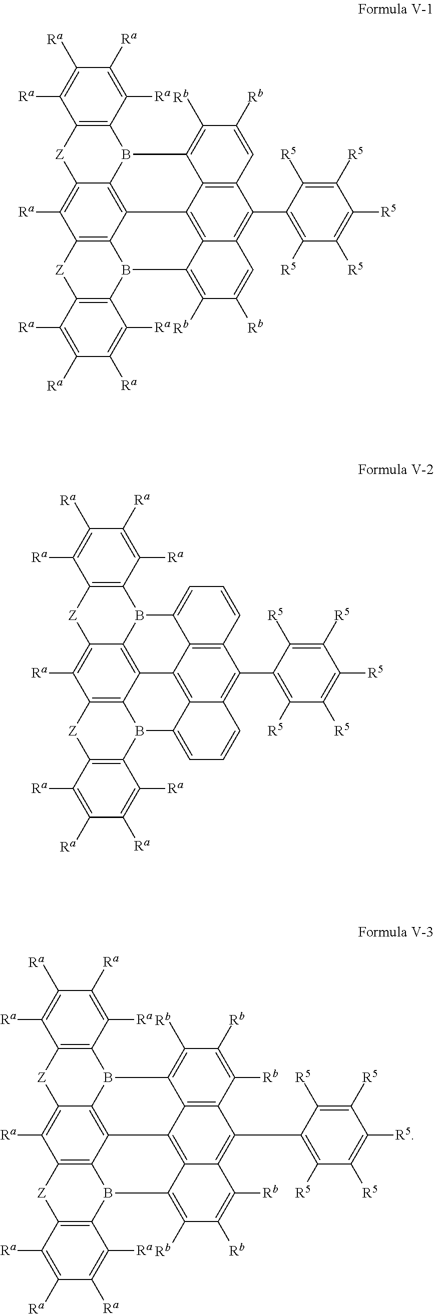

In one embodiment, the organic molecules include or consist of a structure of Formula Va, Formula Vb, Formula Vc, Formula Vd, Formula Ve, Formula Vf, Formula Vg, Formula Vh, Formula Vi, Formula Vj, or Formula Vk:

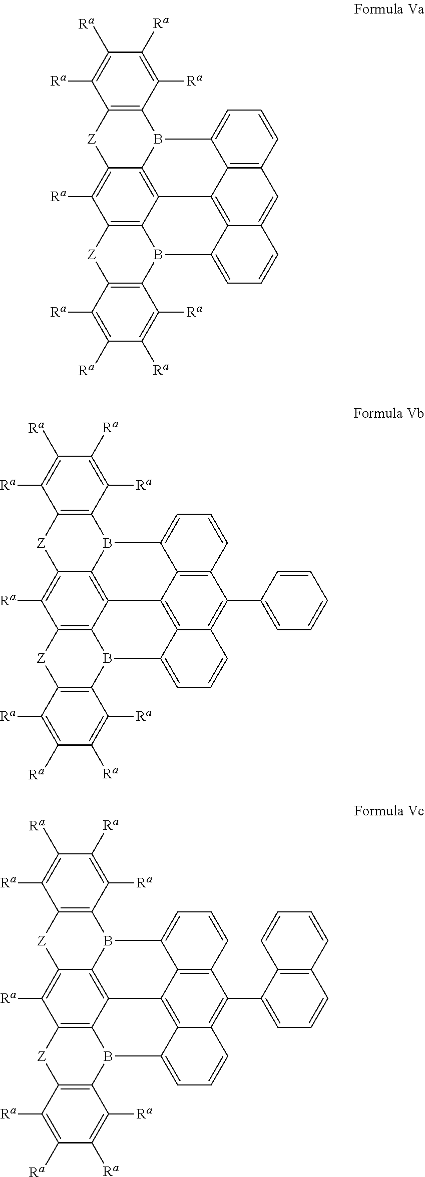

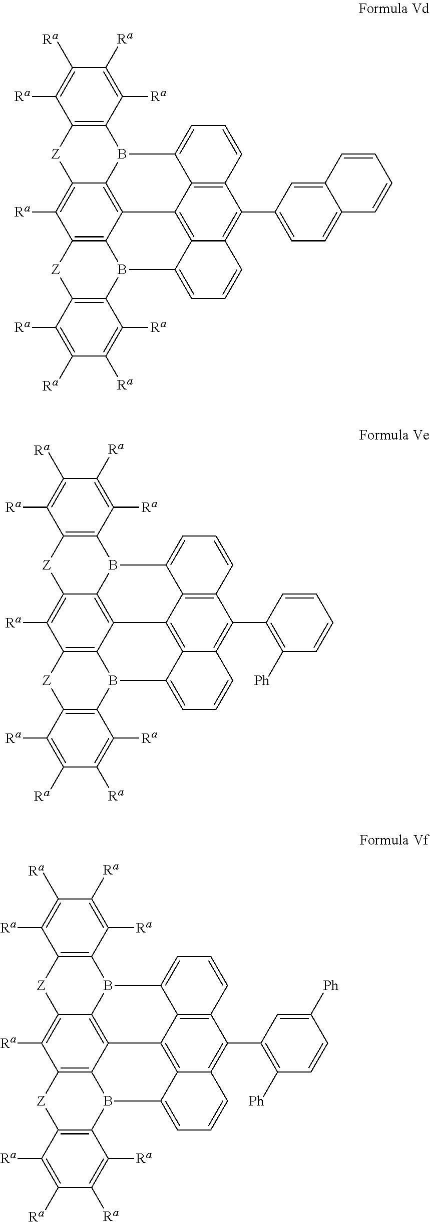

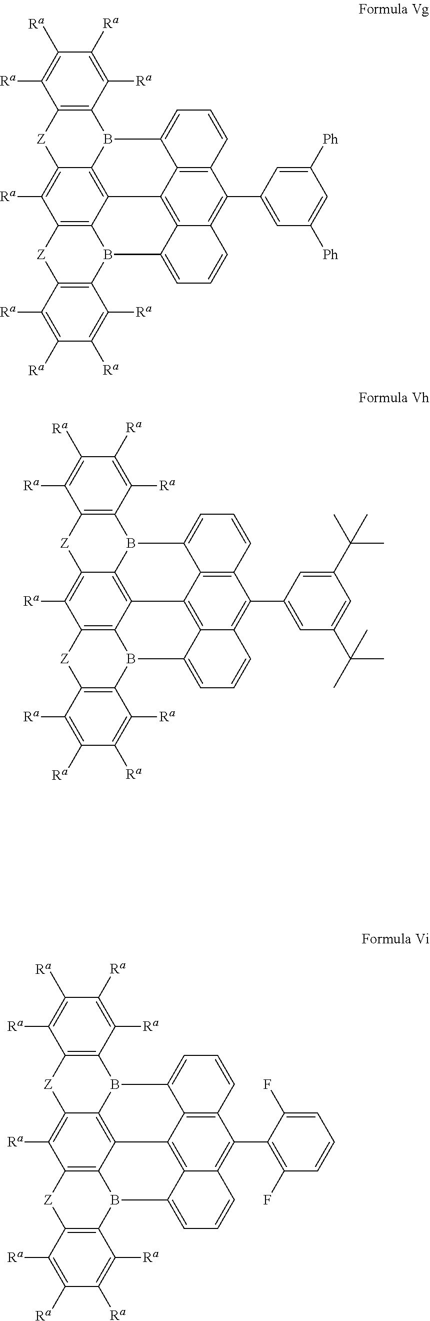

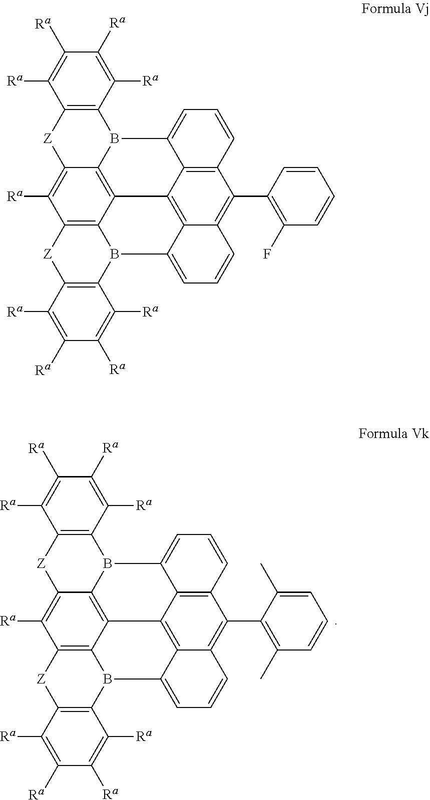

In one embodiment, the organic molecules include or consist of a structure of Formula V-3, wherein adjacent R^{a} substituents independently form a mono- or polycyclic, aliphatic, aromatic, heteroaromatic, and/or benzo-fused ring system.

In one embodiment, the organic molecules include or consist of a structure of Formula V-3a:

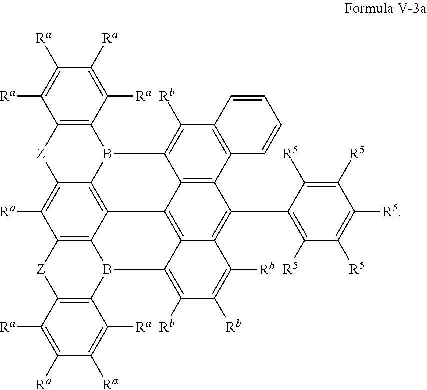

In one embodiment of the invention, R^{b} is at each occurrence independently from each other selected from the group consisting of:
hydrogen,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

The present invention also provides an oligomer for the use as an emitter in an optoelectronic device. The oligomer includes or consists of a plurality (i.e., 2, 3, 4, 5, or 6) of units represented by the Formula VI:

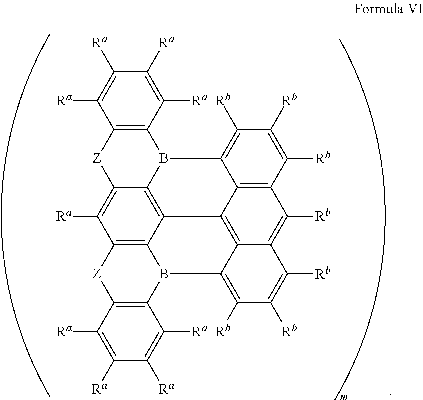

The oligomer is a dimer to hexamer (m=2 to 6), in particular a dimer to trimer (m=2 or 3), or preferably a dimer (m=2). The oligomer
may be in a form having a plurality of the units shown as Formula VI, or
may be in a form in which a plurality of the units shown as Formula VI are linked via a linking group selected from the group consisting of a single bond, an alkylene group having 1 to 3 carbon atoms, a phenylene group, or a naphthylene group, a anthracene group, a pyrene group, or a pyridine group, pyrimidine group, or triazine group, or
may be in a form in which a plurality of the units are linked such that ring a and/or ring b contained in the unit according to Formula VI-AB

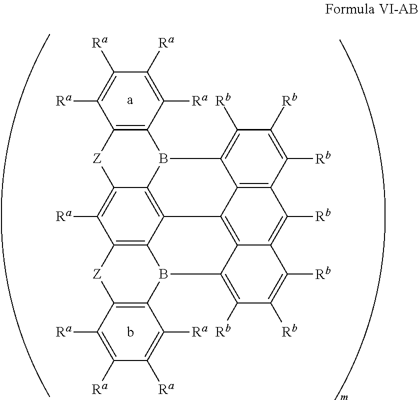

is shared by at least one other adjacent unit of the oligomer, or
may be in a form in which units of the oligomer are linked such that ring a and/or ring b of a unit is fused with ring a and/or ring b of an adjacent unit of the oligomer.

In one embodiment, the organic molecules include or consist of a structure of Formula Villa or Formula VIIIb:

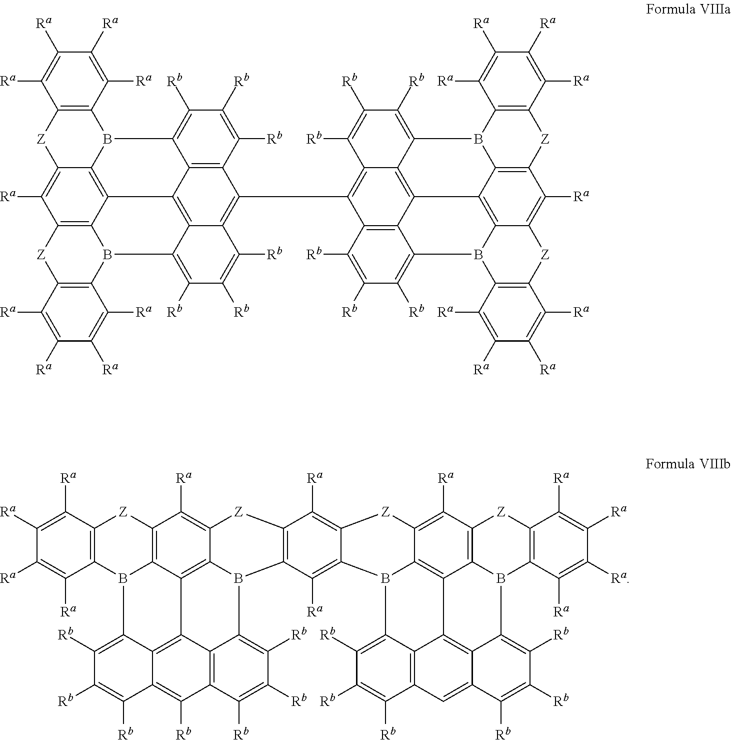

### Definitions

As used throughout the present application, the term “cyclic group” may be understood in the broadest sense as any mono-, bi-, or polycyclic moieties.

As used throughout the present application, the terms “ring” and “ring system” may be understood in the broadest sense as any mono-, bi-, or polycyclic moieties.

As used throughout the present application, the term “carbocycle” may be understood in the broadest sense as any cyclic group in which the cyclic core structure includes only carbon atoms that may of course be substituted with hydrogen or any other substituent(s) defined in the specific embodiments of the invention. It is understood that the term “carbocyclic” as adjective refers to cyclic groups in which the cyclic core structure includes only carbon atoms that may of course be substituted with hydrogen or any other substituent(s) defined in the specific embodiments of the invention.

As used throughout the present application, the term “heterocycle” may be understood in the broadest sense as any cyclic group in which the cyclic core structure includes not just carbon atoms, but also at least one heteroatom. It is understood that the term “heterocyclic” as adjective refers to cyclic groups in which the cyclic core structure includes not just carbon atoms, but also at least one heteroatom. The heteroatoms may, unless stated otherwise in specific embodiments, at each occurrence be the same or different and be individually selected from the group consisting of N, O, S, and Se. All carbon atoms or heteroatoms included in a heterocycle in the context of the invention may of course be substituted with hydrogen or any other substituent(s) defined in the specific embodiments of the invention.

As used throughout the present application, the term “aromatic ring system” may be understood in the broadest sense as any bi- or polycyclic aromatic moiety.

As used throughout the present application, the term “heteroaromatic ring system” may be understood in the broadest sense as any bi- or polycyclic heteroaromatic moiety.

As used throughout the present application, the term “fused” when referring to aromatic or heteroaromatic ring systems means that the aromatic or heteroaromatic rings that are “fused” share at least one bond that is part of both ring systems. For example, naphthalene (or naphthyl when referred to as substituent) or benzothiophene (or benzothiophenyl when referred to as substituent) are considered fused aromatic ring systems in the context of the present invention, in which two benzene rings (for naphthalene) or a thiophene and a benzene (for benzothiophene) share one bond. It is also understood that sharing a bond in this context includes sharing the two atoms that build up the respective bond and that fused aromatic or heteroaromatic ring systems can be understood as one aromatic or heteroaromatic system. Additionally, it is understood, that more than one bond may be shared by the aromatic or heteroaromatic rings building up a fused aromatic or heteroaromatic ring system (e.g., in pyrene). Furthermore, it will be understood that aliphatic ring systems may also be fused and that this has the same meaning as for aromatic or heteroaromatic ring systems, with the exception of course, that fused aliphatic ring systems are not aromatic.

As used throughout the present application, the terms “aryl” and “aromatic” may be understood in the broadest sense as any mono-, bi-, or polycyclic aromatic moieties. Accordingly, an aryl group contains 6 to 60 aromatic ring atoms, and a heteroaryl group contains 5 to 60 aromatic ring atoms, of which at least one is a heteroatom. Notwithstanding, throughout the application the number of aromatic ring atoms may be given as subscripted number in the definition of certain substituents. In particular, the heteroaromatic ring includes one to three heteroatoms. Again, the terms “heteroaryl” and “heteroaromatic” may be understood in the broadest sense as any mono-, bi-, or polycyclic hetero-aromatic moieties that include at least one heteroatom. The heteroatoms may, unless stated otherwise in specific embodiments, at each occurrence be the same or different and be individually selected from the group consisting of N, O, S, and Se. Accordingly, the term “arylene” refers to a divalent substituent that bears two binding sites to other molecular structures and thereby serving as a linker structure. In case, a group in the exemplary embodiments is defined differently from the definitions given here, for example, the number of aromatic ring atoms or number of heteroatoms differs from the given definition, the definition in the exemplary embodiments is to be applied. According to the invention, a condensed (annulated) aromatic or heteroaromatic polycycle is built of two or more single aromatic or heteroaromatic cycles, which formed the polycycle via a condensation reaction.

In particular, as used throughout the present application the term “aryl group” or “heteroaryl group” includes groups which can be bound via any position of the aromatic or heteroaromatic group, derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, selenophene, benzoselenophene, isobenzoselenophene, dibenzoselenophene, pyrrole, indole, isoindole, carbazole, indolocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine, and benzothiadiazole, or combination(s) of the abovementioned groups.

As used throughout the present application, the term “aliphatic” when referring to ring systems may be understood in the broadest sense and means that none of the rings that build up the ring system is an aromatic or heteroaromatic ring. It is understood that such an aliphatic ring system may be fused to one or more aromatic rings so that some (but not all) carbon- or heteroatoms included in the core structure of the aliphatic ring system are part of an attached aromatic ring.

As used above and herein, the term “alkyl group” may be understood in the broadest sense as any linear, branched, or cyclic alkyl substituent. In particular, the term alkyl include the substituents methyl (Me), ethyl (Et), n-propyl (ⁿPr), i-propyl (ⁱPr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluorethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl, or 1-(n-decyl)-cyclohex-1-yl.

As used above and herein, the term “alkenyl” includes any linear, branched, or cyclic alkenyl substituent. The term alkenyl group exemplarily includes the substituents ethenyl, propenyl, butenyl, pentenyl, cyclopentenyl, hexenyl, cyclohexenyl, heptenyl, cycloheptenyl, octenyl, cyclooctenyl, or cyclooctadienyl.

As used above and herein, the term “alkynyl” includes any linear, branched, or cyclic alkynyl substituent. The term alkynyl group exemplarily includes ethynyl, propynyl, butynyl, pentynyl, hexynyl, heptynyl, or octynyl.

As used above and herein, the term “alkoxy” includes any linear, branched, or cyclic alkoxy substituent. The term alkoxy group exemplarily includes methoxy, ethoxy, n-propoxy, i-propoxy, n-butoxy, i-butoxy, s-butoxy, t-butoxy, or 2-methylbutoxy.

As used above and herein, the term “thioalkoxy” includes any linear, branched, or cyclic thioalkoxy substituent, in which the O of the exemplarily alkoxy groups is replaced by S.

As used above and herein, the terms “halogen” and “halo” may be understood in the broadest sense as being preferably fluorine, chlorine, bromine, or iodine.

It is understood that when a molecular fragment is described as being a substituent or otherwise attached to another moiety, its name may be written as if it were a fragment (e.g., naphthyl, dibenzofuryl) or as if it were the whole molecule (e.g., naphthalene, dibenzofuran). As used herein, these different ways of designating a substituent or attached fragment are considered to be equivalent.

All hydrogen atoms (H) included in any structure referred to herein may at each occurrence independently of each other, and without this being indicated specifically, be replaced by deuterium (D). The replacement of hydrogen by deuterium is common practice and obvious for the person skilled in the art. Thus, there are numerous known methods by which this can be achieved and several review articles describing them (see for example: A. Michelotti, M. Roche, Synthesis 2019, 51(06), 1319-1328, DOI: 10.1055/s-0037-1610405; J. Atzrodt, V. Derdau, T. Fey, J. Zimmermann, Angew. Chem. Int. Ed. 2007, 46(15), 7744-7765, DOI: 10.1002/anie.200700039; Y. Sawama, Y. Monguchi, H. Sajiki, Synlett 2012, 23(7), 959-972, DOI: 10.1055/s-0031-1289696.)

It is understood that when a molecular fragment is described as being a substituent or otherwise attached to another moiety, its name may be written as if it were a fragment (e.g., naphthyl, dibenzofuryl) or as if it were the whole molecule (e.g., naphthalene, dibenzofuran). As used herein, these different ways of designating a substituent or attached fragment are considered to be equivalent.

In one embodiment of the invention, the organic molecules according to the invention have an emission peak in the visible or nearest ultraviolet range, i.e., in the range of a wavelength of from 380 nm to 800 nm, with a full width at half maximum of less than 0.35 eV, preferably less than 0.30 eV, more preferably less than 0.26 eV, even more preferably less than 0.22 eV or even less than 0.18 eV in a solution of organic solvent, in particular in dichloromethane (DCM), toluene, or chloroform, of organic molecule or in a film of poly(methyl methacrylate) (PMMA) with 1-5% by weight, in particular with 2% by weight of organic molecule at room temperature.

The energy of the first excited triplet state T1 is determined from the onset of the emission spectrum at low temperature, typically at 77 K. The phosphorescence is usually visible in a steady-state spectrum in a film of 2% emitter and 98% PMMA or in organic solvent, in particular in DCM, toluene, or chloroform. The triplet energy can thus be determined as the onset of the phosphorescence spectrum. For Fluorescent emitter molecules, the energy of the first excited triplet state T1 is determined from the onset of the delayed emission spectrum at 77 K.

The photoluminescence quantum yields of the organic molecules according to the invention are, in particular, 30% or more, preferably more than 50%, more preferably more than 70%, even more preferably more than 80% or even more than 90% in a solution of organic solvent, in particular in dichloromethane (DCM), toluene, or chloroform, of 0.001 mg/mL of organic molecule according to the invention at room temperature.

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

In one embodiment, the organic molecules according to the invention have an onset of the emission spectrum, which is energetically close to the emission maximum, i.e., the energy difference between the onset of the emission spectrum and the energy of the emission maximum is below 0.14 eV, preferably below 0.13 eV, or even below 0.12 eV, while the full width at half maximum (FWHM) of the organic molecules is less than 0.35 eV, preferably less than 0.30 eV, more preferably less than 0.26 eV, even more preferably less than 0.22 eV or even less than 0.18 eV with 0.001 mg/mL of organic molecule according to the invention in toluene or DCM at room temperature.

### Further Aspects and Embodiments of the Invention

A further aspect of the invention relates to the use of an organic molecule of the invention as a luminescent emitter or as an absorber, and/or as a host material and/or as an electron transport material, and/or as a hole injection material, and/or as a hole blocking material in an optoelectronic device.

A preferred embodiment relates to the use of an organic molecule according to the invention as a luminescent emitter in an optoelectronic device.

The optoelectronic device may be understood in the broadest sense as any device based on organic materials that is suitable for emitting light in the visible or nearest ultraviolet (UV) range, i.e., in the range of a wavelength of from 380 to 800 nm. More preferably, the optoelectronic device may be able to emit light in the visible range, i.e., light of from 400 nm to 800 nm.

In the context of such use, the optoelectronic device is more particularly selected from the group consisting of:
organic light-emitting diodes (OLEDs),
light-emitting electrochemical cells,
OLED sensors, especially in gas and vapor sensors that are not hermetically shielded to the surroundings,
organic diodes,
organic solar cells,
organic transistors,
organic field-effect transistors,
organic lasers, and
down-conversion elements.

In a preferred embodiment in the context of such use, the optoelectronic device is a device selected from the group consisting of an organic light emitting diode (OLED), a light emitting electrochemical cell (LEC), and a light-emitting transistor.

In the case of the use, the fraction of the organic molecule according to the invention in the emission layer in an optoelectronic device, more particularly in an OLED, is 0.1% to 99% by weight, more particularly 1% to 80% by weight. In an alternative embodiment, the proportion of the organic molecule in the emission layer is 100% by weight.

In one embodiment, the light-emitting layer includes not only the organic molecules according to the invention, but also a host material whose triplet (T1) and singlet (S1) energy levels are energetically higher than the triplet (T1) and singlet (S1) energy levels of the organic molecule.

### Host Material(s) H^{B}

According to the invention, any of the one or more host materials H^{B} included in any of the at least one light-emitting layers B may be a p-host H^{P} exhibiting high hole mobility, an n-host H^{N} exhibiting high electron mobility, or a bipolar host material H^{BP} exhibiting both, high hole mobility and high electron mobility.

According to the invention, a p-host H^{P} optionally included in any of the at least one light-emitting layers B of an optoelectronic device according to the invention has a highest occupied molecular orbital HOMO(H^{P}) having an energy E^{HOMO}(H^{P}), wherein preferably: −6.1 eV≤E^{HOMO}(H^{P})≤−5.6 eV.

According to the invention, a p-host H^{P} optionally included in any of the at least one light-emitting layers B of an optoelectronic device according to the invention has a lowest unoccupied molecular orbital LUMO(H^{P}) having an energy E^{LUMO}(H^{P}), wherein preferably: −2.6 eV≤E^{LUMO}(H^{P}).

According to the invention, a p-host H^{P} optionally included in any of the at least one light-emitting layers B of an optoelectronic device according to the invention has a lowermost excited singlet state energy level E(S1^{p-H}), wherein preferably: E(S1^{p-H})≤3.0 eV.

According to the invention, a p-host H^{P} optionally included in any of the at least one light-emitting layers B of an optoelectronic device according to the invention has a lowermost excited triplet state energy level E(T1^{p-H}), wherein preferably: E(T1^{p-H)≤}2.7 eV.

It is understood that any requirements or preferred features previously defined for a host material H^{B} included in any of the at least one light-emitting layers B of an optoelectronic device according to the invention are preferably also valid for a p-host H^{P} according to the invention. Thus, in a preferred embodiment, the relations expressed by the following formulas (6) to (9) apply:

E(S1^{p-H})>E(S1^{E}) (6)

E(S1^{p-H})>E(S1^{S}) (7)

E(T1^{p-H})>E(T1^{S}) (8)

E(T1^{p-H})>E(T1^{E}) (9)

Accordingly, the lowermost excited singlet state S1^{p-H} of a p-host H^{P} is preferably higher in energy than the lowermost excited singlet state S1^{E} of a TADF material E^{B}. The lowermost excited singlet state S1^{p-H} of a p-host H^{P} is preferably higher in energy than the lowermost excited singlet state S1^{S} of any small FWHM emitter S^{B}. The lowermost excited triplet state T1^{p-H} of a p-host H^{P} is preferably higher in energy than the lowermost excited triplet state T1^{S} of any small FWHM emitter S^{B}. The lowermost excited triplet state T1^{p-H} of a p-host H^{P} is preferably higher in energy than the lowermost excited triplet state T1^{E} of a TADF material E^{B}.

According to the invention, an n-host H^{N} optionally included in any of the at least one light-emitting layers B of an optoelectronic device according to the invention has a highest occupied molecular orbital HOMO(H^{N}) having an energy E^{HOMO}(H^{N}) wherein preferably: E^{HOMO}(H^{N})≤−5.9 eV.

According to the invention, an n-host H^{N} optionally included in any of the at least one light-emitting layers B of an optoelectronic device according to the invention has a lowest unoccupied molecular orbital LUMO(H^{N}) having an energy E^{LUMO}(H^{N}), wherein preferably: −3.5 eV≤E^{LUMO}(H^{N})≤−2.9 eV.

According to the invention, an n-host H^{N} optionally included in any of the at least one light-emitting layers B of an optoelectronic device according to the invention has a lowermost excited singlet state energy level E(S1^{n-H}), wherein preferably: E(S1^{n-H})≤3.0 eV.

According to the invention, an n-host H^{N} optionally included in any of the at least one light-emitting layers B of an optoelectronic device according to the invention has a lowermost excited triplet state energy level E(T1^{n-H}), wherein preferably: E(T1^{n-H})≤2.7 eV.

It is understood that any requirements or preferred properties previously defined for a host material H^{B} included in any of the at least one light-emitting layers B of an optoelectronic device according to the invention are preferably also valid for an n-host H^{N} according to the invention. Thus, in a preferred embodiment, the relations expressed by the following formulas (10) to (13) apply:

E(S1^{n-H})>E(S1^{E}) (10)

E(S1^{n-H})>E(S1^{S}) (11)

E(T1^{n-H})>E(T1^{S}) (12)

E(T1^{n-H})>E(T1^{E}) (13).

Accordingly, the lowermost excited singlet state S1^{n-H} of an n-host H^{N} is preferably higher in energy than the lowermost excited singlet state S1^{E} of a TADF material E^{B}. The lowermost excited singlet state S1^{n-H} of an n-host H^{N} is preferably higher in energy than the lowermost excited singlet state S1^{S} of any small FWHM emitter S^{B}. The lowermost excited triplet state T1^{n-H} of an n-host H^{N} is preferably higher in energy than the lowermost excited triplet state T1^{S} of any small FWHM emitter S^{B}. Preferably, the lowermost excited triplet state T1^{n-H} of any n-host H^{N} is higher in energy than the lowermost excited triplet state T1^{E} of any TADF material E^{B}.

According to the invention, a bipolar host H^{BP} optionally included in any of the at least one light-emitting layers B of an optoelectronic device according to the invention has a lowest unoccupied molecular orbital LUMO(H^{BP}) having an energy E^{LUMO}(H^{BP}), wherein preferably: −3.5 eV≤E^{LUMO}(H^{BP})≤−2.9 eV.

According to the invention, a bipolar host H^{BP} optionally included in any of the at least one light-emitting layers B of an optoelectronic device according to the invention has a lowermost excited singlet state energy level E(S1^{bp-H}), wherein preferably: E(S1^{bp-H})≤3.0 eV.

According to the invention, a bipolar host H^{BP} optionally included in any of the at least one light-emitting layers B of an optoelectronic device according to the invention has a lowermost excited triplet state energy level E(T1^{bp-H}), wherein preferably: E(T1^{bp-H})≤2.7 eV.

It is understood that any requirements or preferred properties previously defined for a host material H^{B} included in any of the at least one light-emitting layers B of an optoelectronic device according to the invention are preferably also valid for a bipolar host H^{BP} according to the invention. Thus, in a preferred embodiment, the relations expressed by the following formulas (14) to (17) apply:

E(S1^{bp-H})>E(S1^{E}) (14)

E(S1^{bp-H})>E(S1^{S}) (15)

E(T1^{bp-H})>E(T1^{S}) (16)

E(T1^{bp-H})>E(T1^{E}) (17).

Accordingly, the lowermost excited singlet state S1^{bp-H} of a bipolar host H^{BP} is preferably higher in energy than the lowermost excited singlet state S1^{E} of a TADF material E^{B}. The lowermost excited singlet state S1^{bp-H} of a bipolar host H^{BP} is preferably higher in energy than the lowermost excited singlet state S1^{S} of any small FWHM emitter S^{B}. The lowermost excited triplet state T1^{bp-H} of a bipolar host H^{BP} is preferably higher in energy than the lowermost excited triplet state T1^{S} of any small FWHM emitter S^{B}. Preferably, the lowermost excited triplet state T1^{bp-H} of any bipolar host H^{BP} is higher in energy than the lowermost excited triplet state T1^{E} of any TADF material E^{B}.

TADF material(s) E^{B}

According to the invention, any of the one or more thermally activated delayed fluorescence (TADF) materials E^{B} is preferably characterized by exhibiting a ΔE_{ST} value, which corresponds to the energy difference between the lowermost excited singlet state S1^{E} and the lowermost excited triplet state T1^{E}, of less than 0.4 eV, preferably of less than 0.3 eV, more preferably of less than 0.2 eV, even more preferably of less than 0.1 eV, or even of less than 0.05 eV. Thus, ΔE_{ST} of a TADF material E^{B} according to the invention is preferably sufficiently small to allow for thermal repopulation of the lowermost excited singlet state S1^{E} from the lowermost excited triplet state T1^{E} (also referred to as up-intersystem crossing or reverse intersystem crossing) at room temperature (RT).

It is understood that a small FWHM emitter S^{B} included in the at least one light-emitting layer B of an optoelectronic device according to the invention may optionally also have a ΔE_{ST} value of less than 0.4 eV and exhibit thermally activated delayed fluorescence (TADF). However, for any small FWHM emitter S^{B} in the context of the invention, this is only an optional feature. Additionally, a TADF material E^{B} in the context of the invention preferably differs from a small FWHM emitter S^{B} in the context of the invention in that a TADF material E^{B} mainly functions as energy pump transferring energy to at least one small FWHM emitter S^{B} while the main contribution to the emission band of the optoelectronic device according to the invention can preferably be attributed to the emission of at least one small FWHM emitter S^{B}.

According to the invention, a TADF material E^{B} included in any of the at least one light-emitting layers B of an optoelectronic device according to the invention has a highest occupied molecular orbital HOMO(E^{B}) having an energy E^{HOMO}(E^{B}), wherein preferably: −6.0 eV≤E^{HOMO}(E^{B})≤−5.8 eV.

According to the invention, a TADF material E^{B} included in any of the at least one light-emitting layers B of an optoelectronic device according to the invention has a lowest unoccupied molecular orbital LUMO(E^{B}) having an energy E^{LUMO}(E^{B}), wherein preferably: −3.4 eV≤E^{LUMO}(E^{B})≤−3.0 eV.

According to the invention, a TADF material E^{B} included in any of the at least one light-emitting layers B of an optoelectronic device according to the invention has a lowermost excited singlet state energy level E(S1^{E}), wherein preferably: 2.5 eV≤E(S1^{E})≤2.8 eV.

According to the invention, a TADF material E^{B} included in any of the at least one light-emitting layers B of an optoelectronic device according to the invention has a lowermost excited triplet state energy level E(T1^{E}), whose preferred range may be defined by the above-mentioned preferred range for the singlet state energy level E(S1^{E}) in combination with the above-mentioned preferred range for ΔE_{ST}.

A further aspect of the invention relates to a composition including or consisting of:
(a) at least one organic molecule according to the invention, in particular in the form of an emitter, and
(b) one or more triplet-triplet annihilation (TTA) host materials, which differ from the organic molecule according to the invention, and
(c) optionally one or more TADF materials,
(d) optionally one or more dyes and/or one or more solvents.

A further aspect of the invention relates to a composition including or consisting of:
(a) at least one organic molecule according to the invention, in particular in the form of an emitter, and
(b) one or more host materials, which differ from the organic molecule according to the invention, and
(c) one or more TADF materials.

A further aspect of the invention relates to a composition including or consisting of:
(a) at least one organic molecule according to the invention, in particular in the form of an emitter, and
(b) one or more host materials, which differ from the organic molecule according to the invention, and
(c) one or more phosphorescent materials.

In a particular embodiment, the light-emitting layer EML includes (or essentially consists of) a composition including or consisting of:
(i) 0.1-10% by weight, preferably 0.5-5% by weight, in particular 1-3% by weight, of one or more organic molecules according to the invention;
(ii) 5-99% by weight, preferably 15-85% by weight, in particular 20-75% by weight, of at least one host compound H; and
(iii) 0.9-94.9% by weight, preferably 14.5-80% by weight, in particular 24-77% by weight, of at least one further host compound D with a structure differing from the structure of the molecules according to the invention; and
(iv) optionally 0-94% by weight, preferably 0-65% by weight, in particular 0-50% by weight, of a solvent; and
(v) optionally 0-30% by weight, in particular 0-20% by weight, preferably 0-5% by weight, of at least one further emitter molecule F with a structure differing from the structure of the molecules according to the invention.
   Compositions with One or More TTA Host Material

In a preferred embodiment, in the optoelectronic device of the present invention, the light-emitting layer B includes (or consist of):
(i) 10-84% by weight of the TTA material;
(ii) 0-30% by weight of the TADF material E^{B}; and
(iii) 0.1-10% by weight of the emitter according to the invention; and optionally
(iv) 0-89.9% by weight of one or more solvents.

In a preferred embodiment, the percentage numbers of (i)-(iv) sum up to 100% by weight.

In another preferred embodiment, in the optoelectronic device of the present invention, the light-emitting layer B includes (or consist of):
(i) 56-90% by weight of the TTA material;
(ii) 0-5% by weight of the TADF material E^{B}; and
(iii) 0.5-5% by weight of the emitter according to the invention; and optionally
(iv) 0-43.5% by weight of one or more solvents.

In a preferred embodiment, the percentage numbers of (i)-(iv) sum up to 100% by weight.

Compositions with One or More TADF Material

In one embodiment, the light-emitting layer B includes:
(i) 10-89.9% by weight of one or more p-host compound H^{P};
(ii) 0-79.9% by weight of one or more n-host compound H^{N};
(iii) 10-50% by weight of one or more TADF material E^{B}; and
(iv) 0.1-10% by weight of one or more emitter according to the invention; and optionally
(v) 0-89.9% by weight of one or more solvents.

In one embodiment, the light-emitting layer B includes:
(i) 22-87.5% by weight of one or more p-host compound H^{P};
(ii) optionally 0-65.5% by weight of one or more n-host compound H^{N};
(iii) 12-40% by weight of one or more TADF material E^{B}; and
(iv) 0.5-5% by weight of one or more emitter according to the invention; and optionally
(v) 0-65.5% by weight of one or more solvents.
   Compositions with One or More Phosphorescent Material

In a preferred embodiment where H^{N} is optional, in the optoelectronic device of the present invention, the light-emitting layer B includes (or consists of):
(i) 10-84.9% by weight of the host compound H^{P};
(ii) 0-84.9% by weight of the host compound H^{N};
(iii) 5-15% by weight of the Phosphorescence material E^{B}; and
(iv) 0.1-10% by weight of the emitter according to the invention; and optionally
(v) 0-84.9% by weight of one or more solvents.

In a preferred embodiment where H^{N} is optional, in the optoelectronic device of the present invention, the light-emitting layer B includes (or consists of):
(i) 22-70.5% by weight of the host compound H^{P};
(ii) 0-70.5% by weight of the host compound H^{N};
(iii) 5-10% by weight of the phosphorescence material E^{B}; and
(iv) 0.5-5% by weight of the emitter according to the invention; and optionally
(v) 0-72.5% by weight of one or more solvents.

Preferably, energy can be transferred from the host compound H to the one or more organic molecules according to the invention, in particular transferred from the first excited triplet state T1(H) of the host compound H to the first excited triplet state T1(E) of the one or more organic molecules according to the invention E and/or from the first excited singlet state S1(H) of the host compound H to the first excited singlet state S1(E) of the one or more organic molecules according to the invention E.

In one embodiment, the host compound H has a highest occupied molecular orbital HOMO(H) having an energy E_{HOMO}(H) in the range of from −5 to −6.5 eV and the at least one further host compound D has a highest occupied molecular orbital HOMO(D) having an energy E^{HOMO}(D), wherein E^{HOMo}(H)>E^{HOMO}(D).

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E_{LUMO}(D).

In one embodiment, the host compound H has a highest occupied molecular orbital HOMO(H) having an energy E^{HOMO}(H) and a lowest unoccupied molecular orbital LUMO(H) having an energy E^{LUMO}(H), and

the at least one further host compound D has a highest occupied molecular orbital HOMO(D) having an energy E^{HOMO}(D) and a lowest unoccupied molecular orbital LUMO(D) having an energy E^{LUMO}(D),
the organic molecule according to the invention E has a highest occupied molecular orbital HOMO(E) having an energy E^{HOMO}(E) and a lowest unoccupied molecular orbital LUMO(E) having an energy E^{LUMO}(E),
wherein
E^{HOMO}(H)>E^{HOMO}(D) and the difference between the energy level of the highest occupied molecular orbital HOMO(E) of the organic molecule according to the invention E (E_{HOMO}(E)) and the energy level of the highest occupied molecular orbital HOMO(H) of the host compound H (E^{HOMO}(H)) is between −0.5 eV and 0.5 eV, more preferably between −0.3 eV and 0.3 eV, even more preferably between −0.2 eV and 0.2 eV or even between −0.1 eV and 0.1 eV; and
E^{LUMO}(H)>E^{LUMO}(D) and the difference between the energy level of the lowest unoccupied molecular orbital LUMO(E) of the organic molecule according to the invention E (E^{LUMO}(E)) and the lowest unoccupied molecular orbital LUMO(D) of the at least one further host compound D (E^{LUMO}(D)) is between −0.5 eV and 0.5 eV, more preferably between −0.3 eV and 0.3 eV, even more preferably between −0.2 eV and 0.2 eV or even between −0.1 eV and 0.1 eV.

In one embodiment of the invention the host compound D and/or the host compound H is a thermally-activated delayed fluorescence (TADF)-material. TADF materials exhibit a ΔE_{ST} value, which corresponds to the energy difference between the first excited singlet state (S1) and the first excited triplet state (T1), of less than 2500 cm⁻¹. Preferably the TADF material exhibits a ΔE_{ST} value of less than 3000 cm⁻¹, more preferably less than 1500 cm⁻¹, even more preferably less than 1000 cm⁻¹ or even less than 500 cm⁻¹.

In one embodiment, the host compound D is a TADF material and the host compound H exhibits a ΔE_{ST} value of more than 2500 cm⁻¹. In a particular embodiment, the host compound D is a TADF material and the host compound H is selected from group consisting of CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, and 9-[3,5-bis(2-dibenzothiophenyl)phenyl]-9H-carbazole.

In one embodiment, the host compound H is a TADF material and the host compound D exhibits a ΔE_{ST} value of more than 2500 cm⁻¹. In a particular embodiment, the host compound H is a TADF material and the host compound D is selected from group consisting of T2T (2,4,6-tris(biphenyl-3-yl)-1,3,5-triazine), T3T (2,4,6-tris(triphenyl-3-yl)-1,3,5-triazine), and/or TST (2,4,6-tris(9,9′-spirobifluoren-2-yl)-1,3,5-triazine).

In a further aspect, the invention relates to an optoelectronic device including an organic molecule or a composition of the type described here, more particularly in the form of a device selected from the group consisting of organic light-emitting diodes (OLED), light-emitting electrochemical cells, OLED sensors (particularly gas and vapor sensors not hermetically externally shielded), organic diodes, organic solar cells, organic transistors, organic field-effect transistors, organic lasers, and down-conversion element.

In a preferred embodiment, the optoelectronic device is a device selected from the group consisting of an organic light emitting diode (OLED), a light emitting electrochemical cell (LEC), and a light-emitting transistor.

In one embodiment of the optoelectronic device of the invention, the organic molecule according to the invention E is used as emission material in a light-emitting layer EML.

In one embodiment of the optoelectronic device of the invention, the light-emitting layer EML consists of the composition according to the invention described here.

When the optoelectronic device is an OLED, it may, for example, have the following layer structure:
1. substrate
2. anode layer A
3. hole injection layer, HIL
4. hole transport layer, HTL
5. electron blocking layer, EBL
6. light-emitting layer, EML
7. hole blocking layer, HBL
8. electron transport layer, ETL
9. electron injection layer, EIL
10. cathode layer C,
wherein the OLED includes each layer selected from the group of HIL, HTL, EBL, HBL, ETL, and EIL only optionally, different layers may be merged and the OLED may include more than one layer of each layer type defined above.

Furthermore, the optoelectronic device may, in one embodiment, include one or more protective layers protecting the device from damaging exposure to harmful species in the environment including, for example, moisture, vapor, and/or gases.

In one embodiment of the invention, the optoelectronic device is an OLED, with the following inverted layer structure:
1. substrate
2. cathode layer C
3. electron injection layer, EIL
4. electron transport layer, ETL
5. hole blocking layer, HBL
6. light-emitting layer, B
7. electron blocking layer, EBL
8. hole transport layer, HTL
9. hole injection layer, HIL
10. anode layer A
wherein the OLED includes each layer selected from the group of HIL, HTL, EBL, HBL, ETL, and EIL only optionally, different layers may be merged and the OLED may include more than one layer of each layer types defined above.

In one embodiment of the invention, the optoelectronic device is an OLED, which may have a stacked architecture. In this architecture, contrary to the typical arrangement in which the OLEDs are placed side by side, the individual units are stacked on top of each other. Blended light may be generated with OLEDs exhibiting a stacked architecture, in particular white light may be generated by stacking blue, green, and red OLEDs. Furthermore, the OLED exhibiting a stacked architecture may include a charge generation layer (CGL), which is typically located between two OLED subunits and typically consists of a n-doped and p-doped layer with the n-doped layer of one CGL being typically located closer to the anode layer.

In one embodiment of the invention, the optoelectronic device is an OLED, which includes two or more emission layers between anode and cathode. In particular, this so-called tandem OLED includes three emission layers, wherein one emission layer emits red light, one emission layer emits green light, and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

The substrate may be formed by any material or composition of materials. Most frequently, glass slides are used as substrates. Alternatively, thin metal layers (e.g., copper, gold, silver, or aluminum films) or plastic films or slides may be used. This may allow for a higher degree of flexibility. The anode layer A is mostly composed of materials allowing to obtain an (essentially) transparent film. As at least one of both electrodes should be (essentially) transparent in order to allow light emission from the OLED, either the anode layer A or the cathode layer C is transparent. Preferably, the anode layer A includes a large content or even consists of transparent conductive oxides (TCOs). Such anode layer A may, for example, include indium tin oxide, aluminum zinc oxide, fluorine doped tin oxide, indium zinc oxide, PbO, SnO, zirconium oxide, molybdenum oxide, vanadium oxide, tungsten oxide, graphite, doped Si, doped Ge, doped GaAs, doped polyaniline, doped polypyrrole, and/or doped polythiophene.

The anode layer A (essentially) may consist of indium tin oxide (ITO) (e.g., (In₂O₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (i.e., holes) in that the transport of the quasi charge carriers from the TCO to the hole transport layer (HTL) is facilitated. The hole injection layer (HIL) may include poly-3,4-ethylenedioxy thiophene (PEDOT), polystyrene sulfonate (PSS), MoO₂, V₂O₅, CuPC, or CuI, in particular a mixture of PEDOT and PSS. The hole injection layer (HIL) may also prevent the diffusion of metals from the anode layer A into the hole transport layer (HTL). The HIL may, for example, include PEDOT:PSS (poly-3,4-ethylenedioxy thiophene: polystyrene sulfonate), PEDOT (poly-3,4-ethylenedioxy thiophene), mMTDATA (4,4′,4″-tris[phenyl(m-tolyl)amino]triphenylamine), Spiro-TAD (2,2′,7,7′-tetrakis(N,N-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-bis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile), and/or Spiro-NPD (N,N′-diphenyl-N,N′-bis-(1-naphthyl)-9,9′-spirobifluorene-2,7-diamine).

Adjacent to the anode layer A or hole injection layer (HIL), a hole transport layer (HTL) is typically located. Herein, any hole transport compound may be used. For example, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). Preferably, hole transport compounds bear comparably high energy levels of their triplet states T1. For example, the hole transport layer (HTL) may include a star-shaped heterocycle such as tris(4-carbazol-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN, and/or TrisPcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide, or tungsten oxide may, for example, be used as inorganic dopant. Tetrafluorotetracyanoquinodimethane (F₄-TCNQ), copper-pentafluorobenzoate (Cu(I)pFBz), or transition metal complexes may, for example, be used as organic dopant.

The EBL may, for example, include mCP (1,3-bis(carbazol-9-yl)benzene), TCTA, 2-TNATA, mCBP (3,3-di(9H-carbazol-9-yl)biphenyl), tris-Pcz, CzSi (9-(4-tert-Butylphenyl)-3,6-bis(triphenylsilyl)-9H-carbazole), and/or DCB (N,N′-dicarbazolyl-1,4-dimethylbenzene).

Adjacent to the hole transport layer (HTL), the light-emitting layer EML is typically located. The light-emitting layer EML includes at least one light emitting molecule. Particularly, the EML includes at least one light emitting molecule according to the invention E. In one embodiment, the light-emitting layer includes only the organic molecules according to the invention. Typically, the EML additionally includes one or more host materials H. For example, the host material H is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl] ether oxide), 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine), and/or TST (2,4,6-tris(9,9′-spirobifluoren-2-yl)-1,3,5-triazine). The host material H typically should be selected to exhibit first triplet (T1) and first singlet (S1) energy levels, which are energetically higher than the first triplet (T1) and first singlet (S1) energy levels of the organic molecule.

In one embodiment of the invention, the EML includes a so-called mixed-host system with at least one hole-dominant host and one electron-dominant host. In a particular embodiment, the EML includes exactly one light emitting organic molecule according to the invention and a mixed-host system including T2T as electron-dominant host and a host selected from CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, and 9-[3,5-bis(2-dibenzothiophenyl)phenyl]-9H-carbazole as hole-dominant host. In a further embodiment the EML includes 50-80% by weight, preferably 60-75% by weight, of a host selected from CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, and 9-[3,5-bis(2-dibenzothiophenyl)phenyl]-9H-carbazole; 10-45% by weight, preferably 15-30% by weight, of T2T; and 5-40% by weight, preferably 10-30% by weight, of light emitting molecule according to the invention.

Adjacent to the light-emitting layer EML, an electron transport layer (ETL) may be located. Herein, any electron transporter may be used. Exemplarily, electron-poor compounds such as, e.g., benzimidazoles, pyridines, triazoles, oxadiazoles (e.g., 1,3,4-oxadiazole), phosphine oxides, and sulfone, may be used. An electron transporter may also be a star-shaped heterocycle such as 1,3,5-tri(1-phenyl-1H-benzo[d]imidazol-2-yl)phenyl (TPBi). The ETL may include NBphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphine oxide), BPyTP2 (2,7-di(2,2′-bipyridin-5-yl)triphenylene), Sif87 (dibenzo[b,d]thiophen-2-yltrphenylsilane), Sif88 (dibenzo[b,d]thiophen-2-yl)diphenylsilane), BmPyPhB (1,3-bis[3,5-di(pyridin-3-yl)phenyl]benzene), and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a hole blocking layer (HBL) is introduced.

The HBL may, for example, include BCP (2,9-dimethyl-4,7-diphenyl-1,10-phenanthroline=Bathocuproine), BAIq (bis(8-hydroxy-2-methylquinoline)-(4-phenylphenoxy)aluminum), NBphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphine oxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluoren-2-yl)-1,3,5-triazine), and/or TCB/TCP (1,3,5-tris(N-carbazolyl)benzene/ 1,3,5-tris(carbazol-9-yl) benzene).

Adjacent to the electron transport layer (ETL), a cathode layer C may be located. The cathode layer C may, for example, include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) intransparent metals such as Mg, Ca, or Al. Alternatively or additionally, the cathode layer C may also include graphite and or carbon nanotubes (CNTs). Alternatively, the cathode layer C may also consist of nanoscale silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO, and/or NaF.

Optionally, the electron transport layer (ETL) and/or a hole blocking layer (HBL) may also include one or more host compounds H.

In order to modify the emission spectrum and/or the absorption spectrum of the light-emitting layer EML further, the light-emitting layer EML may further include one or more further emitter molecules F. Such an emitter molecule F may be any emitter molecule known in the art. Preferably such an emitter molecule F is a molecule with a structure differing from the structure of the molecules according to the invention E. The emitter molecule F may optionally be a TADF emitter. Alternatively, the emitter molecule F may optionally be a fluorescent and/or phosphorescent emitter molecule which is able to shift the emission spectrum and/or the absorption spectrum of the light-emitting layer EML. Exemplarily, the triplet and/or singlet excitons may be transferred from the organic emitter molecule according to the invention to the emitter molecule F before relaxing to the ground state S0 by emitting light typically red-shifted in comparison to the light emitted by an organic molecule. Optionally, the emitter molecule F may also provoke two-photon effects (i.e., the absorption of two photons of half the energy of the absorption maximum).

Optionally, an optoelectronic device (e.g., an OLED) may, for example, be an essentially white optoelectronic device. For example, such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:
violet: wavelength range of >380-420 nm;
deep blue: wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to emitter molecules, such colors refer to the emission maximum. Therefore, for example, a deep blue emitter has an emission maximum in the range of from >420 to 480 nm, a sky blue emitter has an emission maximum in the range of from >480 to 500 nm, a green emitter has an emission maximum in a range of from >500 to 560 nm, a red emitter has an emission maximum in a range of from >620 to 800 nm.

A red emitter may preferably have an emission maximum of below 800 nm, more preferably below 700 nm, even more preferably below 665 nm or even below 640 nm. It will typically be above 570 nm, preferably above 590 nm, more preferably above 610 nm or even above 620 nm.

Accordingly, a further aspect of the present invention relates to an OLED, which exhibits an external quantum efficiency at 1000 cd/m² of more than 8%, more preferably of more than 10%, more preferably of more than 13%, even more preferably of more than 15% or even more than 20% and/or exhibits an emission maximum between 590 nm and 690 nm, preferably between 610 nm and 665 nm, even more preferably between 620 nm and 640 nm and/or exhibits a LT80 value at 500 cd/m² of more than 100 h, preferably more than 200 h, more preferably more than 400 h, even more preferably more than 750 h or even more than 1000 h. Accordingly, a further aspect of the present invention relates to an OLED, whose emission exhibits a CIEy color coordinate of more than 0.25, preferably more than 0.27, more preferably more than 0.29, or even more preferably more than 0.30.

A further embodiment of the present invention relates to an OLED, which emits light with CIEx and CIEy color coordinates close to the CIEx (=0.708) and CIEy (=0.292) color coordinates of the primary color red (CIEx=0.708 and CIEy=0.292) as defined by ITU-R Recommendation BT.2020 (Rec. 2020) and thus is suited for the use in Ultra High Definition (UHD) displays, e.g., UHD-TVs. In this context, the term “close to” refers to the ranges of CIEx and CIEy coordinates provided at the end of this paragraph. In commercial applications, typically top-emitting (top-electrode is transparent) devices are used, whereas test devices as used throughout the present application represent bottom-emitting devices (bottom-electrode and substrate are transparent). Accordingly, a further aspect of the present invention relates to an OLED, whose emission exhibits a CIEx color coordinate of between 0.60 and 0.88, preferably between 0.61 and 0.83, more preferably between 0.63 and 0.78, or even more preferably between 0.66 and 0.76 or even between 0.68 and 0.73 and/or a CIEy color coordinate of between 0.25 and 0.70, preferably between 0.26 and 0.55, more preferably between 0.27 and 0.45, or even more preferably between 0.28 and 0.40 or even between 0.29 and 0.35.

Accordingly, a further aspect of the present invention relates to an OLED, which exhibits an external quantum efficiency at 14500 cd/m² of more than 10%, more preferably of more than 13%, more preferably of more than 15%, even more preferably of more than 17% or even more than 20% and/or exhibits an emission maximum between 590 nm and 690 nm, preferably between 610 nm and 665 nm, even more preferably between 620 nm and 640 nm.

A further aspect of the present invention relates to an OLED, which emits light at a distinct color point. According to the present invention, the OLED emits light with a narrow emission band (small full width at half maximum (FWHM)). In one aspect, the OLED according to the invention emits light with a FWHM of the main emission peak of less than 0.30 eV, preferably less than 0.25 eV, more preferably less than 0.20 eV, even more preferably less than 0.19 eV or even less than 0.17 eV.

In a further aspect, the invention relates to a method for producing an optoelectronic component. In this case an organic molecule of the invention is used.

The optoelectronic device, in particular the OLED according to the present invention can be fabricated by any means of vapor deposition and/or liquid processing. Accordingly, at least one layer is
prepared by means of a sublimation process,
prepared by means of an organic vapor phase deposition process,
prepared by means of a carrier gas sublimation process, or
solution processed or printed.

The methods used to fabricate the optoelectronic device, in particular the OLED according to the present invention are known in the art. The different layers are individually and successively deposited on a suitable substrate by means of subsequent deposition processes. The individual layers may be deposited using the same or differing deposition methods.

Vapor deposition processes, for example, include thermal (co)evaporation, chemical vapor deposition, and/or physical vapor deposition. For active matrix OLED display, an AMOLED backplane is used as substrate. The individual layer may be processed from solutions or dispersions employing adequate solvents. Solution deposition process, for example, include spin coating, dip coating, and/or jet printing. Liquid processing may optionally be carried out in an inert atmosphere (e.g., in a nitrogen atmosphere) and the solvent may be completely or partially removed by means known in the state of the art.

### EXAMPLES

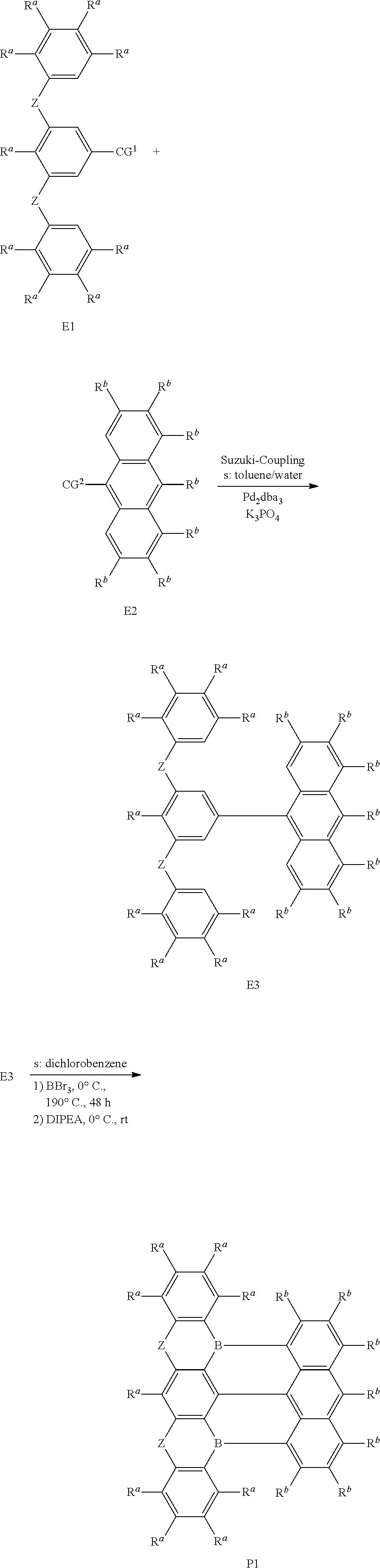

The coupling groups CG¹ and CG² are chosen as a reaction pair to introduce the heterocycle of E2 at the position of CG¹. Preferably, a so-called Suzuki coupling reaction is used. Here, either CG¹ is chosen from Cl, Br, or I, and CG² is a boronic acid group or a boronic acid ester group, in particular a boronic acid pinacol ester group, or CG¹ is a boronic acid group or a boronic acid ester group, in particular a boronic acid pinacol ester group, and CG² is chosen from Cl, Br, or I.

### General Procedure for Synthesis:

### AAV1-1:

E1 (1.00 equivalents, e.g., 5-bromo-N1,N1,N3,N3-tetraphenyl-1,3-benzenediamine, CAS 1290039-73-4), E2 (1.20 equivalents; e.g., (10-phenylanthracen-9-yl)boronic acid, CAS: 1290039-73-4), tris(dibenzylideneacetone)dipalladium(0) (0.01 equivalents; CAS: 51364-51-3), S-Phos (0.04 equivalents; CAS: 657408-07-6), and potassium phosphate (K₃PO₄; CAS: 7778-53-2, 2.00 equivalents) were stirred under nitrogen atmosphere in toluene/water at 95° C. for 72 h. After cooling down to room temperature (rt), the reaction mixture was extracted between ethyl acetate and water. The organic phases were collected, dried over MgSO₄, treated with Celite® and charcoal, stirred for 1 h and filtered. The combined organic layers concentrated under reduced pressure. The crude was purified by column chromatography or recrystallization, and E3 was obtained as a solid.

AAV2: A solution of E-3 (1.0 equivalent) in dry 1,2-dichlorobenzene (35 mL per 1 mmol E-3) was added boron tribromide (99%, CAS-No. 10294-33-4, 4.0 equivalents). The mixture was allowed to warm to rt, followed by heating to 190° C. for 48 h. The mixture was allowed to cool down to rt. Subsequently, the mixture was extracted between brine/water and dichloromethane and the combined organic layers were dried over MgSO₄, filtered, and concentrated. After purification through recrystallization or column chromatography, the target compound P-1 was obtained as a solid.

### Cyclic Voltammetry

Cyclic voltammograms are measured from solutions having concentration of 10⁻³ mol/L of the organic molecules in dichloromethane or a suitable solvent and a suitable supporting electrolyte (e.g., 0.1 mol/L of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data is corrected using ferrocene (FeCp₂) as internal standard against a saturated calomel electrode (SCE).

### Density Functional Theory Calculation

Molecular structures are optimized employing the BP86 functional and the resolution of identity approach (RI). Excitation energies are calculated using the (BP86) optimized structures employing Time-Dependent DFT (TD-DFT) methods. Orbital and excited state energies are calculated with the B3LYP functional. Def2-SVP basis sets (and a m4-grid for numerical integration are used. The Turbomole program package is used for all calculations.

### Photophysical Measurements

Sample pretreatment: Spin-coating
Apparatus: Spin150, SPS euro.
The sample concentration is 0.2 mg/ml, dissolved in Toluene/DCM.
Program: 7) 30 sec. at 2000 U/min. After coating, the films are dried at 70° C. for 1 min.

### Fluorescence Spectroscopy and Phosphorescence Spectroscopy

For the analysis of Phosphorescence and Photoluminescence spectroscopy, a fluorescence spectrometer “Fluoromax 4P” from Horiba is used.

Time-Resolved PL Spectroscopy in the μs-Range and ns-Range (FS5)

Time-resolved PL measurements were performed on a FS5 fluorescence spectrometer from Edinburgh Instruments. Compared to measurements on the HORIBA setup, better light gathering allows for an optimized signal to noise ratio, which favors the FS5 system especially for transient PL measurements of delayed fluorescence characteristics. The FS5 consists of a xenon lamp providing a broad spectrum. The continuous light source is a 150W xenon arc lamp, selected wavelengths are chosen by a Czerny-Turner monochromator, which is also used to set specific emission wavelengths. The sample emission is directed towards a sensitive R928P photomultiplier tube (PMT), allowing the detection of single photons with a peak quantum efficiency of up to 25% in the spectral range between 200 nm to 870 nm. The detector is a temperature stabilized PMT, providing dark counts below 300 cps (counts per second). Finally, to determine the transient decay lifetime of the delayed fluorescence, a tail fit using three exponential functions is applied. By weighting the specific lifetimes τᵢ with their corresponding amplitudes Aᵢ,

$${τ}_{DF} = {\sum }_{i = 1}^{3} \frac{{A}_{i} {τ}_{i}}{{A}_{i}}$$

the delayed fluorescence lifetime τ_{DF} is determined.

### Photoluminescence Quantum Yield Measurements

For photoluminescence quantum yield (PLQY) measurements, an Absolute PL Quantum Yield Measurement C9920-03G system (Hamamatsu Photonics) is used. Quantum yields and CIE coordinates are determined using the software U6039-05 version 3.6.0.

Emission maxima are given in nm, quantum yields ϕ in % and CIE coordinates as x, y values.

PLQY is determined using the following protocol:
Quality assurance: Anthracene in ethanol (known concentration) is used as reference
Excitation wavelength: the absorption maximum of the organic molecule is determined and the molecule is excited using this wavelength

### Measurement

Quantum yields are measured, for sample, of solutions or films under nitrogen atmosphere. The yield is calculated using the equation:

$${Φ}_{PL} = \frac{{n}_{photon ,} emitted}{{n}_{photon ,} absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ} ,$$

wherein nₚₕₒₜₒₙ denotes the photon count and Int. the intensity.

### Measurement of the Emission Spectrum

The material was dissolved in chloroform and the solution filtered through a syringe filter. Remaining solution was used to spin coat a 2% film in PMMA. Sample was excited at 291 nm and a 495 nm filter was used for the measurement.

### Production and Characterization of Optoelectronic Devices

Optoelectronic devices, such as OLED devices, including organic molecules according to the invention can be produced via vacuum-deposition methods. If a layer contains more than one compound, the weight-percentage of one or more compounds is given in %. The total weight-percentage values amount to 100%, thus if a value is not given, the fraction of this compound equals to the difference between the given values and 100%.

The not fully optimized OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, LT 95 to the time point, at which the measured luminance decreased to 95% of the initial luminance etc.

Accelerated lifetime measurements are performed (e.g., applying increased current densities). For example, LT80 values at 500 cd/m² are determined using the following equation:

$$LT 80 ( 500 \frac{{cd}^{2}}{{m}^{2}} ) = LT 80 ( {L}_{0} ) {( \frac{{L}_{0}}{500 \frac{{cd}^{2}}{{m}^{2}}} )}^{1.6} ,$$

wherein L₀ denotes the initial luminance at the applied current density.

The values correspond to the average of several pixels (typically two to eight), the standard deviation between these pixels is given.

### HPLC-MS

HPLC-MS analysis is performed on an HPLC by Agilent (1260 series) with MS-detector (Thermo LTQ XL).

For example, a typical HPLC method is as follows: a reverse phase column 3.0 mm×100 mm, particle size 2.7 μm from Agilent (Poroshell 120EC-C18, 3.0 mm×100 mm, 2.7 μm HPLC column) is used in the HPLC. The HPLC-MS measurements are performed at room temperature (rt) following gradients

| Flow rate [ml/min] | Time [min] | A[%] | B[%] | C[%] |
|---|---|---|---|---|
| 1.5 | 30 | 40 | 40 | 30 |
| 1.5 | 45 | 10 | 10 | 80 |
| 1.5 | 50 | 40 | 10 | 80 |
| 1.5 | 51 | 30 | 40 | 30 |
| 1.5 | 55 | 30 | 10 | 30 |

using the following solvent mixtures containing 0.1% formic acid:

| | | |
|---|---|---|
| Solvent A: | H₂O (10%) | MeCN (90%) |
| Solvent B: | H₂O (90%) | MeCN (10%) |
| Solvent C: | THF (50%) | MeCN (50%) |

An injection volume of 2 μL from a solution with a concentration of 0.5 mg/mL of the analyte is taken for the measurements.

Ionization of the probe is performed using an atmospheric pressure chemical ionization (APCI) source either in positive (APCI+) or negative (APCI−) ionization mode or an atmospheric pressure photoionization (APPI) source.

### Example 1

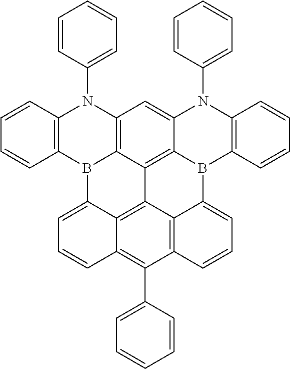 [SMILES: c1ccc(-c2c3cccc4c3c3c5c(cccc25)B2c5ccccc5N(c5ccccc5)c5cc6c(c-3c52)B4c2ccccc2N6c2ccccc2)cc1]

### Example 1 was Synthesized According to General Synthesis Scheme and According to

AAV1-1 (46% yield), wherein 5-bromo-N1,N1,N3,N3-tetraphenyl-1,3-benzenediamine (CAS 1290039-73-4) was used as reactant E1 and (10-phenylanthracen-9-yl)boronic acid (CAS 1290039-73-4) was used as reactant E2; and

AAV2 (2% yield).

MS (HPLC-MS), m/z (retention time): 681 (6.63 min).

The emission maximum (λₘₐₓ) of example 1 (0.005 mg/mL in toluene) is at 658 nm, the full width at half maximum (FWHM) is 82 nm (0.22 eV), and the photoluminescence quantum yield (PLQY) is 38%.

### 1 Additional Examples of Organic Molecules of the Invention

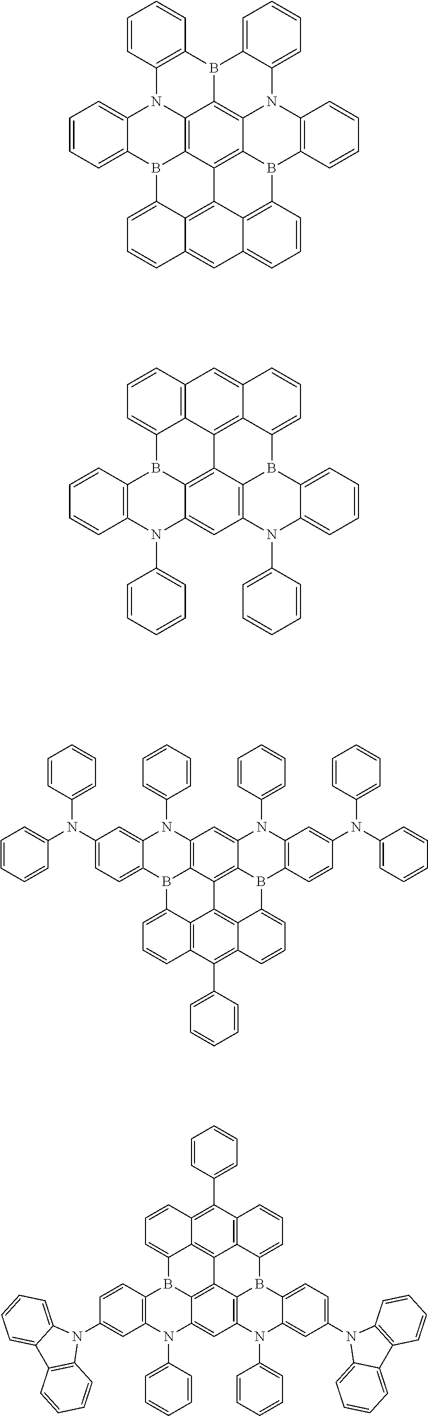 [SMILES: c1ccc2c(c1)B1c3ccccc3N3c4ccccc4B4c5c6c7c(c1c53)N2c1ccccc1B7c1cccc2cc3cccc4c3c-6c12 ; c1ccc(N2c3ccccc3B3c4c2cc2c5c4-c4c6c3cccc6cc3cccc(c43)B5c3ccccc3N2c2ccccc2)cc1 ; c1ccc(-c2c3cccc4c3c3c5c(cccc25)B2c5ccc(N(c6ccccc6)c6ccccc6)cc5N(c5ccccc5)c5cc6c(c-3c52)B4c2ccc(N(c3ccccc3)c3ccccc3)cc2N6c2ccccc2)cc1 ; c1ccc(-c2c3cccc4c3c3c5c(cccc25)B2c5ccc(-n6c7ccccc7c7ccccc76)cc5N(c5ccccc5)c5cc6c(c-3c52)B4c2ccc(-n3c4ccccc4c4ccccc43)cc2N6c2ccccc2)cc1]

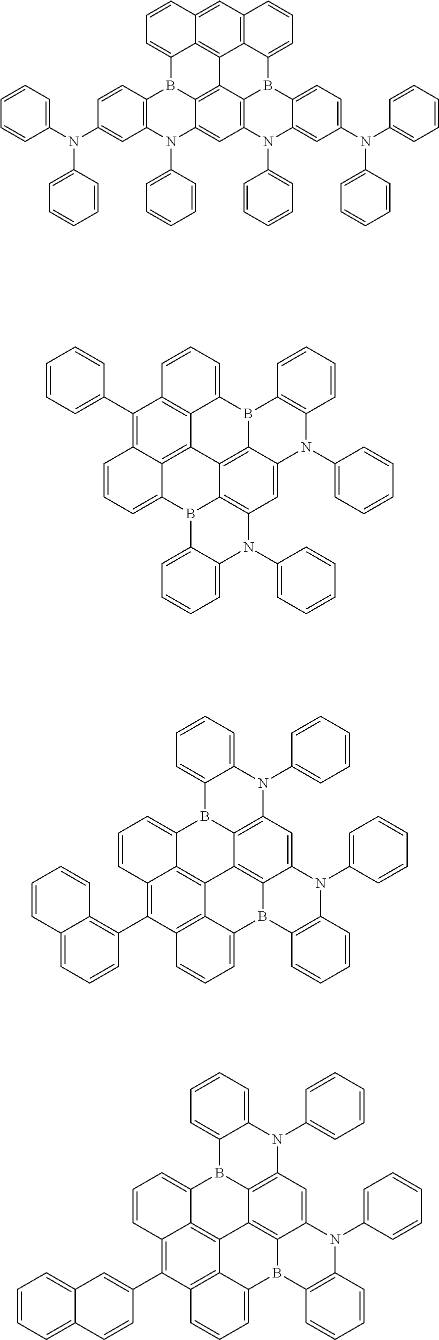 [SMILES: c1ccc(N(c2ccccc2)c2ccc3c(c2)N(c2ccccc2)c2cc4c5c6c2B3c2cccc3cc7cccc(c7c-6c23)B5c2ccc(N(c3ccccc3)c3ccccc3)cc2N4c2ccccc2)cc1 ; c1ccc(-c2c3cccc4c3c3c5c(cccc25)B2c5ccccc5N(c5ccccc5)c5cc6c(c-3c52)B4c2ccccc2N6c2ccccc2)cc1 ; c1ccc(N2c3ccccc3B3c4c2cc2c5c4-c4c6c3cccc6c(-c3cccc6ccccc36)c3cccc(c43)B5c3ccccc3N2c2ccccc2)cc1 ; c1ccc(N2c3ccccc3B3c4c2cc2c5c4-c4c6c3cccc6c(-c3ccc6ccccc6c3)c3cccc(c43)B5c3ccccc3N2c2ccccc2)cc1]

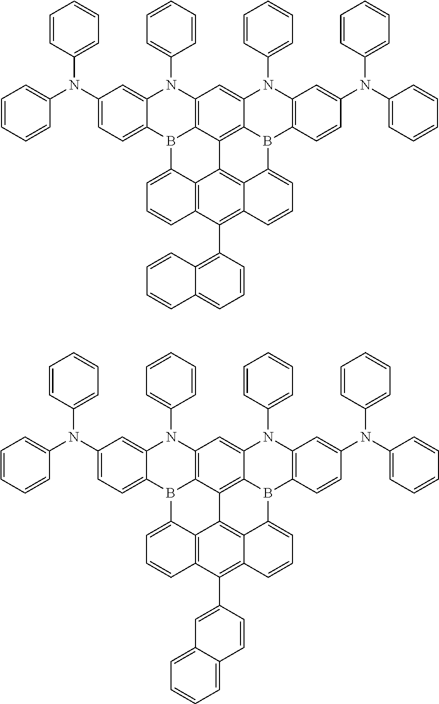 [SMILES: c1ccc(N(c2ccccc2)c2ccc3c(c2)N(c2ccccc2)c2cc4c5c6c2B3c2cccc3c(-c7cccc8ccccc78)c7cccc(c7c-6c23)B5c2ccc(N(c3ccccc3)c3ccccc3)cc2N4c2ccccc2)cc1 ; c1ccc(N(c2ccccc2)c2ccc3c(c2)N(c2ccccc2)c2cc4c5c6c2B3c2cccc3c(-c7ccc8ccccc8c7)c7cccc(c7c-6c23)B5c2ccc(N(c3ccccc3)c3ccccc3)cc2N4c2ccccc2)cc1]

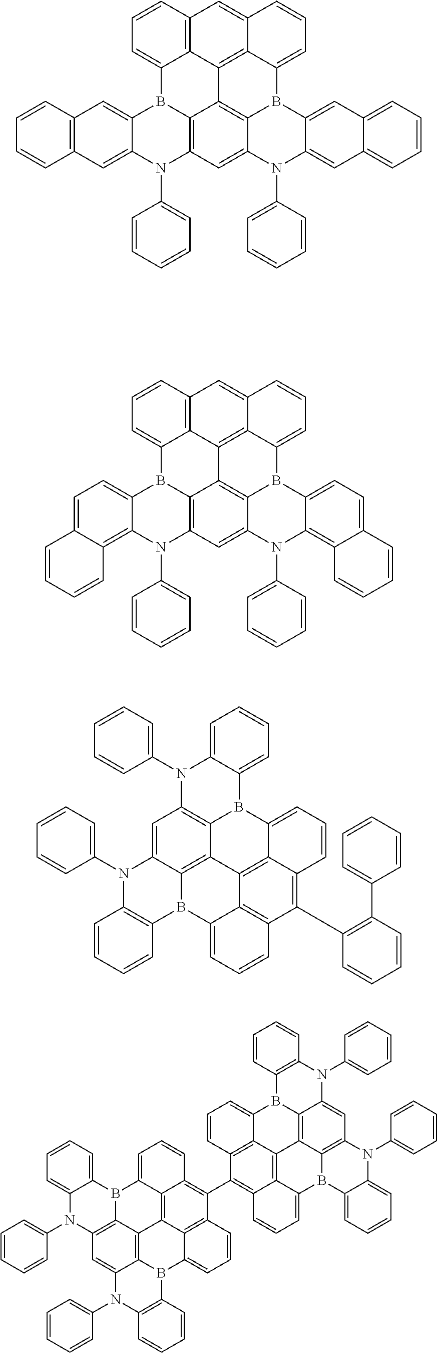

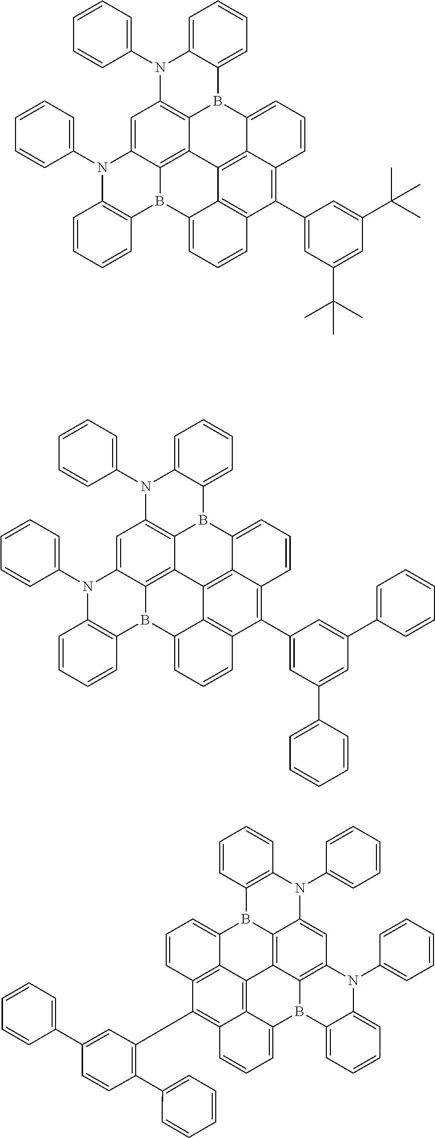 [SMILES: CC(C)(C)c1cc(-c2c3cccc4c3c3c5c(cccc25)B2c5ccccc5N(c5ccccc5)c5cc6c(c-3c52)B4c2ccccc2N6c2ccccc2)cc(C(C)(C)C)c1 ; c1ccc(-c2cc(-c3ccccc3)cc(-c3c4cccc5c4c4c6c(cccc36)B3c6ccccc6N(c6ccccc6)c6cc7c(c-4c63)B5c3ccccc3N7c3ccccc3)c2)cc1 ; c1ccc(-c2ccc(-c3ccccc3)c(-c3c4cccc5c4c4c6c(cccc36)B3c6ccccc6N(c6ccccc6)c6cc7c(c-4c63)B5c3ccccc3N7c3ccccc3)c2)cc1]

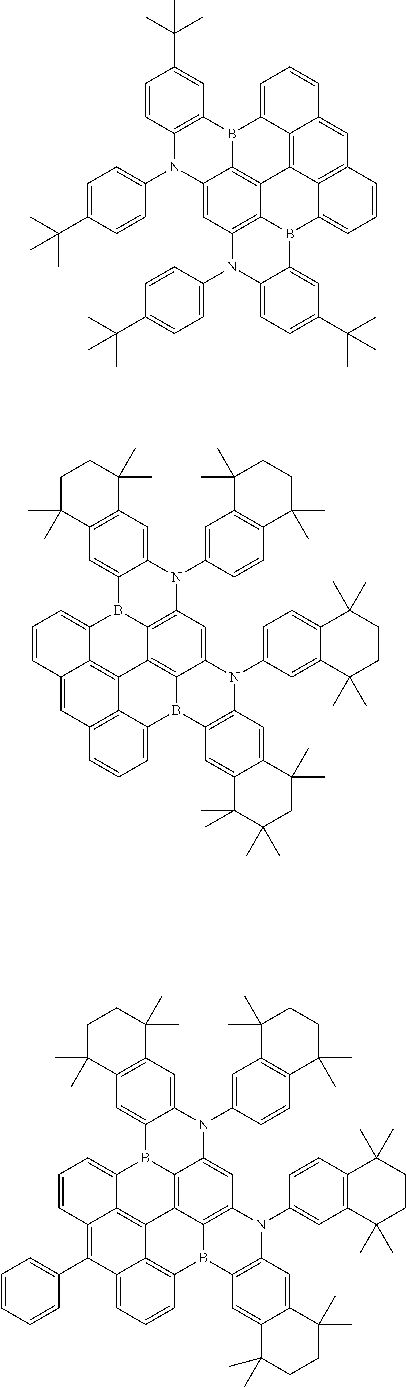

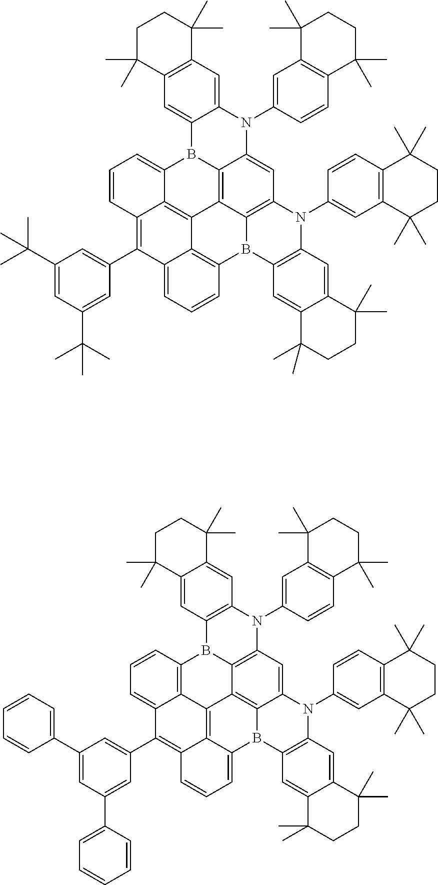 [SMILES: CC(C)(C)c1cc(-c2c3cccc4c3c3c5c(cccc25)B2c5cc6c(cc5N(c5ccc7c(c5)C(C)(C)CCC7(C)C)c5cc7c(c-3c52)B4c2cc3c(cc2N7c2ccc4c(c2)C(C)(C)CCC4(C)C)C(C)(C)CCC3(C)C)C(C)(C)CCC6(C)C)cc(C(C)(C)C)c1 ; CC1(C)CCC(C)(C)c2cc(N3c4cc5c(cc4B4c6c3cc3c7c6-c6c8c4cccc8c(-c4cc(-c8ccccc8)cc(-c8ccccc8)c4)c4cccc(c64)B7c4cc6c(cc4N3c3ccc4c(c3)C(C)(C)CCC4(C)C)C(C)(C)CCC6(C)C)C(C)(C)CCC5(C)C)ccc21]

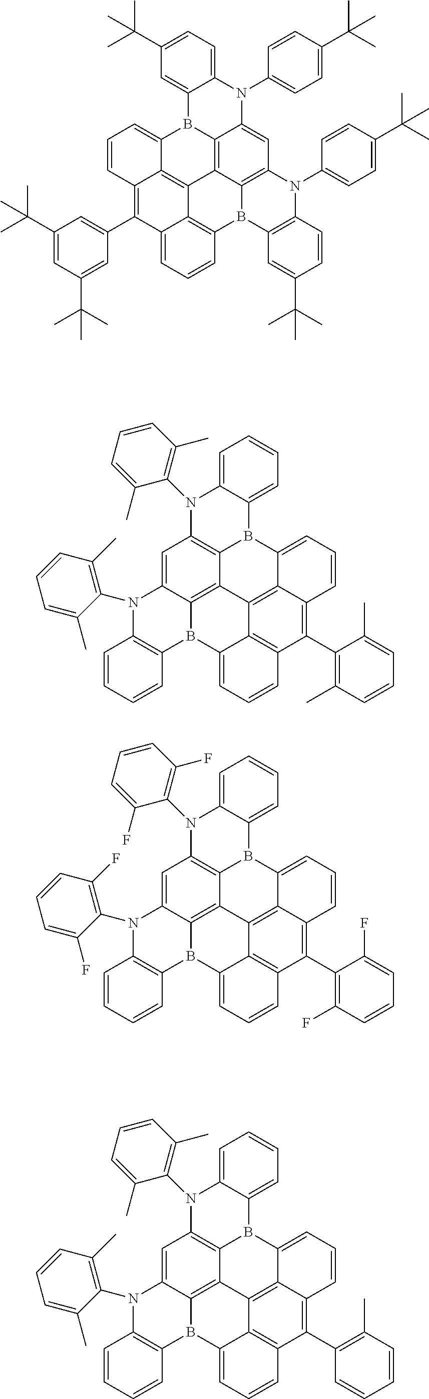

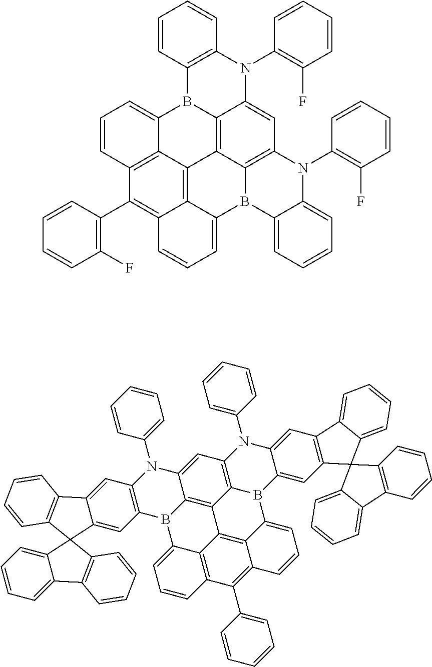 [SMILES: Fc1ccccc1-c1c2cccc3c2c2c4c(cccc14)B1c4ccccc4N(c4ccccc4F)c4cc5c(c-2c41)B3c1ccccc1N5c1ccccc1F ; c1ccc(-c2c3cccc4c3c3c5c(cccc25)B2c5cc6c(cc5N(c5ccccc5)c5cc7c(c-3c52)B4c2cc3c(cc2N7c2ccccc2)-c2ccccc2C32c3ccccc3-c3ccccc32)-c2ccccc2C62c3ccccc3-c3ccccc32)cc1]

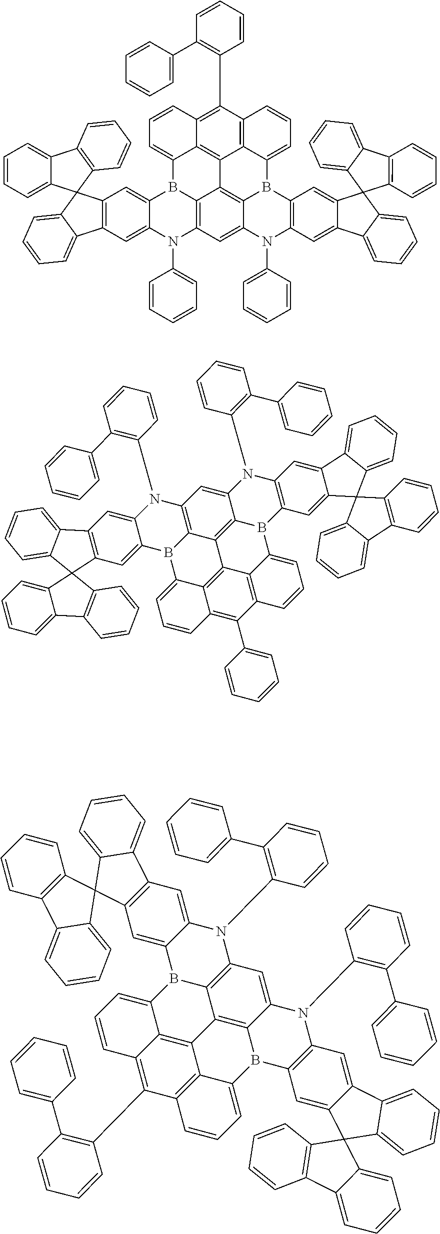

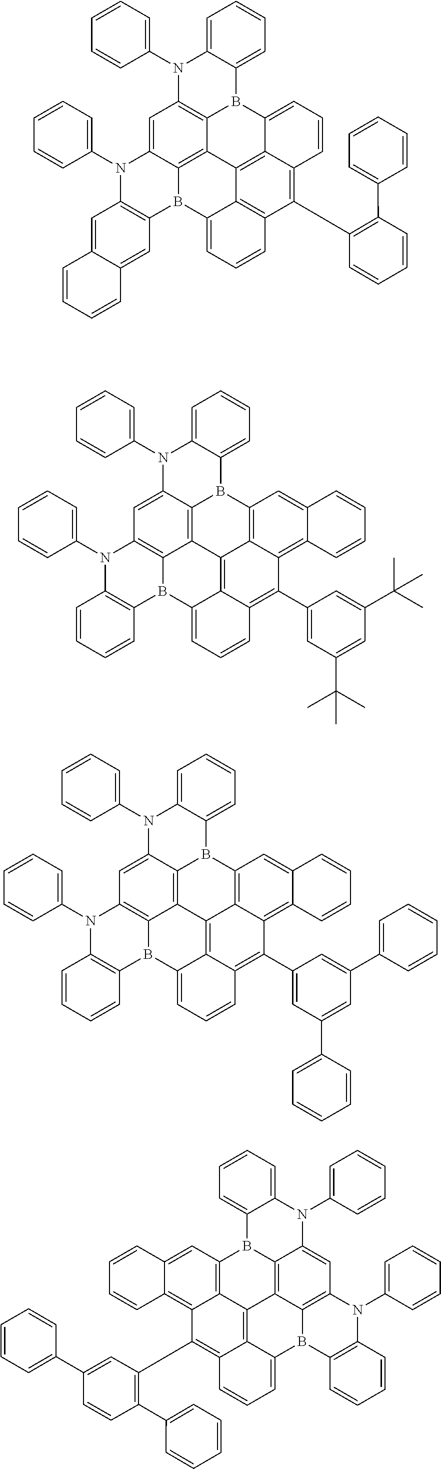

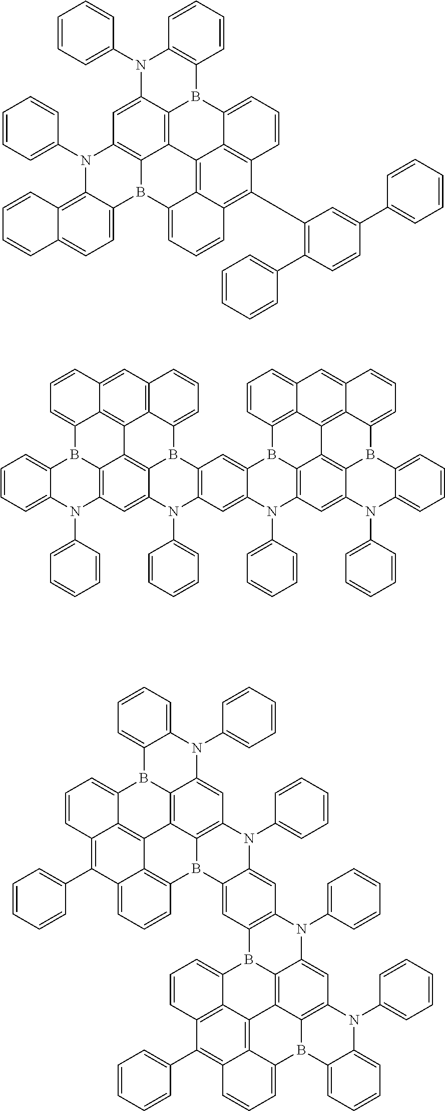 [SMILES: c1ccc(-c2ccc(-c3ccccc3)c(-c3c4cccc5c4c4c6c(cccc36)B3c6ccc7ccccc7c6N(c6ccccc6)c6cc7c(c-4c63)B5c3ccccc3N7c3ccccc3)c2)cc1 ; c1ccc(N2c3ccccc3B3c4c2cc2c5c4-c4c6c3cccc6cc3cccc(c43)B5c3cc4c(cc3N2c2ccccc2)N(c2ccccc2)c2cc3c5c6c2B4c2cccc4cc7cccc(c7c-6c24)B5c2ccccc2N3c2ccccc2)cc1 ; c1ccc(-c2c3cccc4c3c3c5c(cccc25)B2c5cc6c(cc5N(c5ccccc5)c5cc7c(c-3c52)B4c2ccccc2N7c2ccccc2)N(c2ccccc2)c2cc3c4c5c2B6c2cccc6c(-c7ccccc7)c7cccc(c7c-5c26)B4c2ccccc2N3c2ccccc2)cc1]

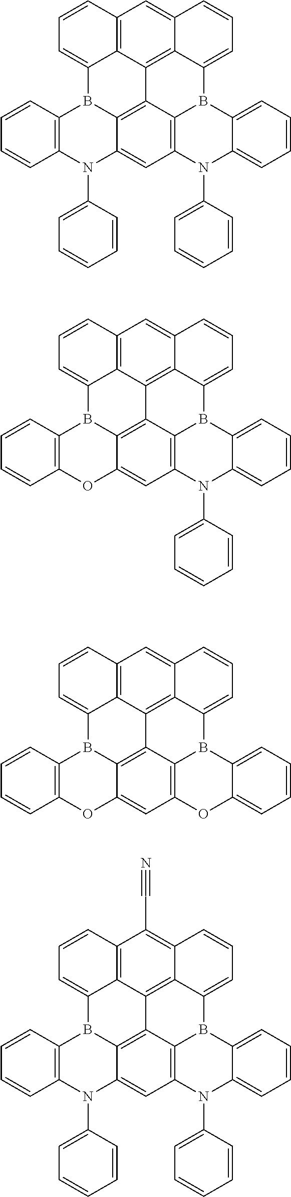 [SMILES: c1ccc(N2c3ccccc3B3c4c2cc2c5c4-c4c6c3cccc6cc3cccc(c43)B5c3ccccc3N2c2ccccc2)cc1 ; c1ccc(N2c3ccccc3B3c4c2cc2c5c4-c4c6c(cccc6cc6cccc3c46)B5c3ccccc3O2)cc1 ; c1ccc2c(c1)Oc1cc3c4c5c1B2c1cccc2cc6cccc(c6c-5c12)B4c1ccccc1O3 ; N#Cc1c2cccc3c2c2c4c(cccc14)B1c4ccccc4N(c4ccccc4)c4cc5c(c-2c41)B3c1ccccc1N5c1ccccc1]

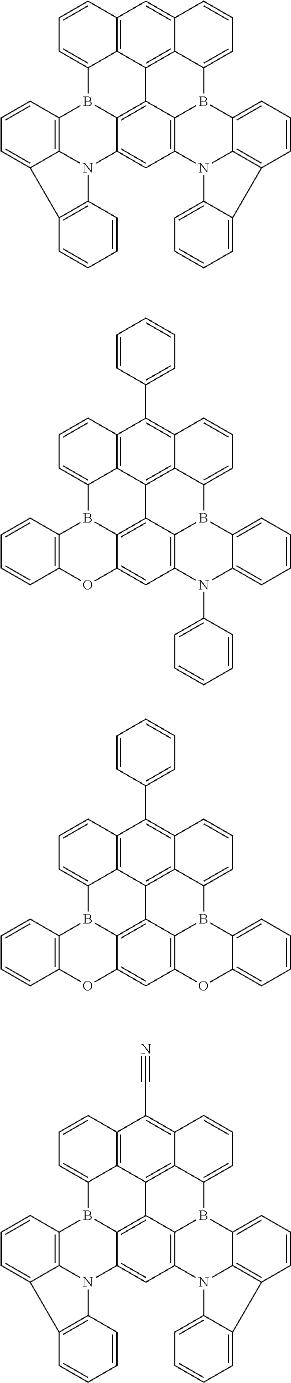 [SMILES: c1cc2c3c4c5c(cccc5cc3c1)B1c3c(cc5c(c3-4)B2c2cccc3c4ccccc4n-5c23)-n2c3ccccc3c3cccc1c32 ; c1ccc(-c2c3cccc4c3c3c5c(cccc25)B2c5ccccc5N(c5ccccc5)c5cc6c(c-3c52)B4c2ccccc2O6)cc1 ; c1ccc(-c2c3cccc4c3c3c5c(cccc25)B2c5ccccc5Oc5cc6c(c-3c52)B4c2ccccc2O6)cc1 ; N#Cc1c2cccc3c2c2c4c(cccc14)B1c4c(cc5c(c4-2)B3c2cccc3c4ccccc4n-5c23)-n2c3ccccc3c3cccc1c32]

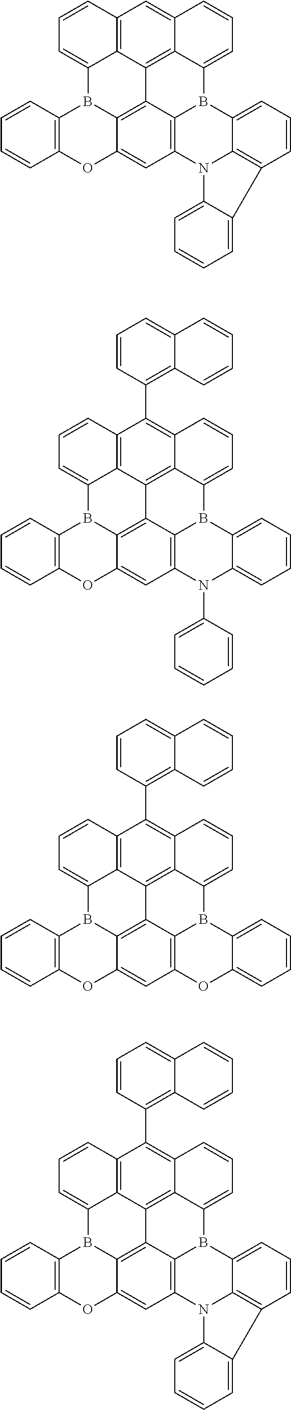

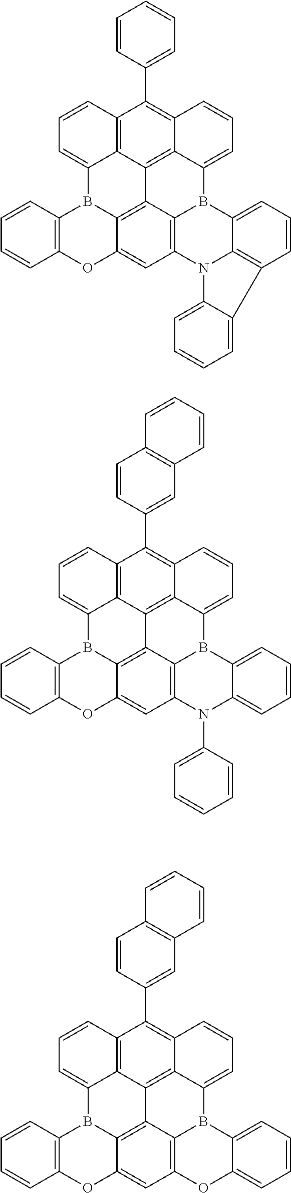

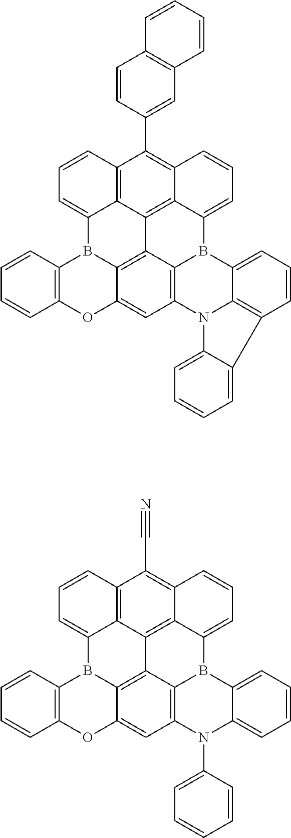 [SMILES: c1ccc2c(c1)Oc1cc3c4c5c1B2c1cccc2c(-c6ccc7ccccc7c6)c6cccc(c6c-5c12)B4c1cccc2c4ccccc4n-3c12 ; N#Cc1c2cccc3c2c2c4c(cccc14)B1c4ccccc4N(c4ccccc4)c4cc5c(c-2c41)B3c1ccccc1O5]

The invention claimed is:

1.-15. (canceled)

16. An organic molecule, comprising a structure of Formula I: 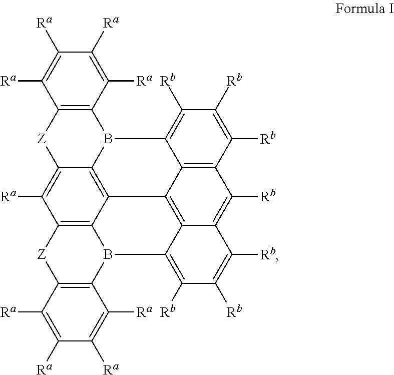
wherein
Z is at each occurrence independently from each other selected from the group consisting of a direct bond, NR^{a}, O, and S; and
R^{a} and R^{b} are at each occurrence independently selected from the group consisting of: hydrogen; deuterium; N(R⁵)₂; OR⁵; Si(R⁵)₃; B(OR⁵)₂; B(R⁵)₂; OSO₂R⁵; CF₃; CN; F; Br; I;
C₁-C₄₀-alkyl,
which is optionally substituted with one or more substituents R⁵ and
wherein one or more non-adjacent CH₂-groups are optionally substituted by R⁵C═CR⁵, C↓C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one or more non-adjacent CH₂-groups are optionally substituted by R⁵C═CR⁵, C↓C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C↓C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one or more non-adjacent CH₂-groups are optionally substituted by R⁵C═CR⁵, C↓C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one or more non-adjacent CH₂-groups are optionally substituted by R⁵C═CR⁵, C↓C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₂-C₅₇-heteroaryl,
which is optionally substituted with one or more substituents R⁵;
R⁵ is at each occurrence independently from each other selected from the group consisting of: hydrogen; deuterium; N(R⁶)₂; OR⁶; Si(R⁶)₃; B(OR⁶)₂; B(R⁶)₂; OSO₂R⁶; CF₃; CN; F; Br; I;
C₁-C₄₀-alkyl,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-alkoxy,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-thioalkoxy,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkenyl,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkynyl,
which is optionally substituted with one or more substituents R⁶ and
wherein one or more non-adjacent CH₂-groups are optionally substituted by R⁶C═CR⁶, C↓C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₆-C₆₀-aryl,
which is optionally substituted with one or more substituents R⁶; and
C₂-C₅₇-heteroaryl,
which is optionally substituted with one or more substituents R⁶;
R⁶ is at each occurrence independently from each other selected from the group consisting of: hydrogen; deuterium; OPh; CF₃; CN; F;
C₁-C₅-alkyl,
wherein one or more hydrogen atoms are optionally, independently substituted by deuterium, CN, CF₃, or F;
C₁-C₅-alkoxy,
wherein one or more hydrogen atoms are optionally, independently substituted by deuterium, CN, CF₃, or F;
C₁-C₅-thioalkoxy,
wherein one or more hydrogen atoms are optionally, independently substituted by deuterium, CN, CF₃, or F;
C₂-C₅-alkenyl,
wherein one or more hydrogen atoms are optionally, independently substituted by deuterium, CN, CF₃, or F;
C₂-C₅-alkynyl,
wherein one or more hydrogen atoms are optionally, independently substituted by deuterium, CN, CF₃, or F;
C₆-C₁₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl); and
wherein, optionally, any of the substituents R^{a}, R^{b}, R⁵, and R⁶ independently forms a mono- or polycyclic, aliphatic, aromatic, heteroaromatic, and/or benzo-fused ring system with one or more other substituents R^{a}, R^{b}, R⁵ and/or R⁶.

17. The organic molecule according to claim 16, comprising a structure of Formula II-1 or Formula II-2:

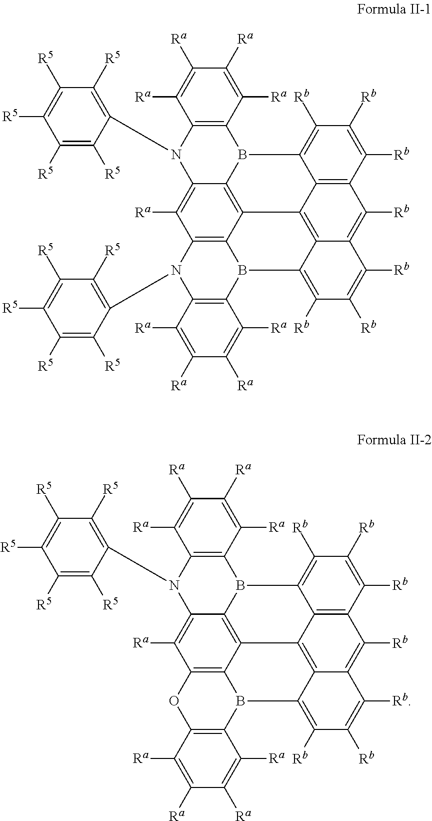

18. The organic molecule according to claim 16, wherein R⁵ is at each occurrence independently from each other selected from the group consisting of:
hydrogen,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

19. The organic molecule according to claim 16, wherein R⁵ is at each occurrence independently from each other selected from the group consisting of:
hydrogen,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

20. The organic molecule according to claim 16, comprising a structure of Formula IIa-1: 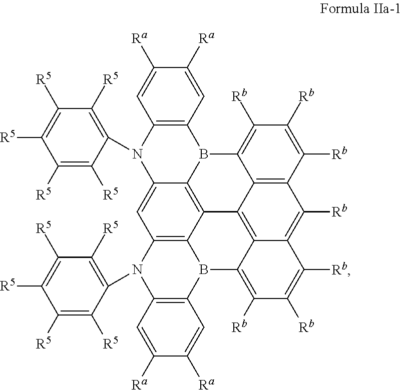
wherein adjacent Re substituents independently form a mono- or polycyclic, aliphatic, aromatic, heteroaromatic, and/or benzo-fused ring system.

21. The organic molecule according to claim 16, comprising a structure of Formula V-1, Formula V-2, or Formula V-3:

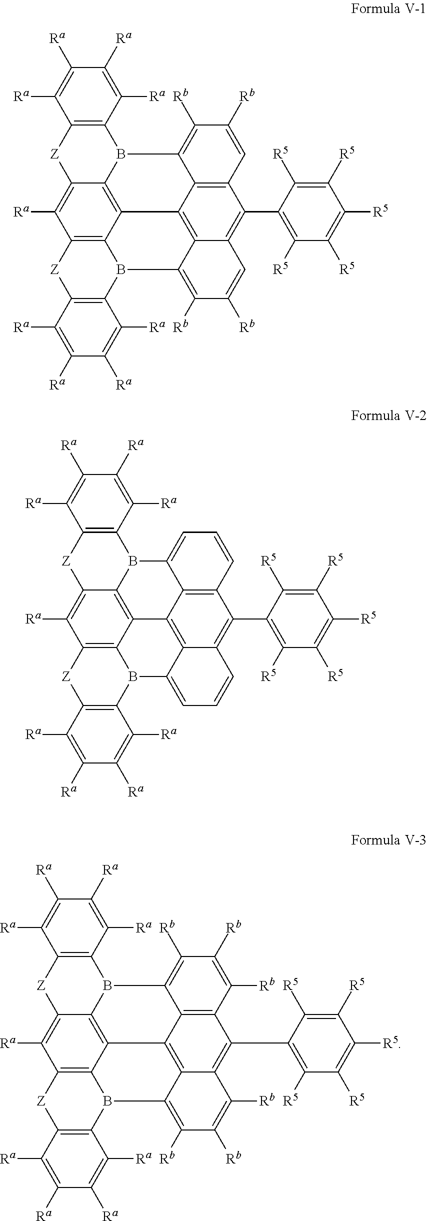

22. The organic molecule according to claim 16, wherein R^{b} is at each occurrence independently from each other selected from the group consisting of:
hydrogen,
Me,
ⁱPr,
Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

23. An oligomer, comprising a plurality of organic molecules according to claim 16 as units, wherein each unit comprises a structure represent by Formula VI: 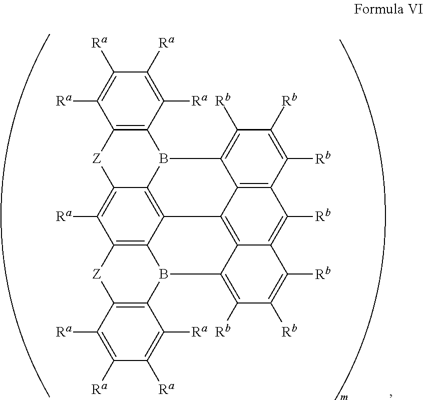
in Formula VI, m being an integer from 2 to 6.

24. An optoelectronic device, comprising the organic molecule according to claim 16 as a luminescent emitter.

25. The optoelectronic device according to claim 24, wherein the optoelectronic device is selected from the group consisting of:
organic light-emitting diodes (OLEDs),
light-emitting electrochemical cells,
OLED-sensors,
organic diodes,
organic solar cells,
organic transistors,
organic field-effect transistors,
organic lasers,
down-conversion elements, and
combinations thereof.

26. A composition, comprising:
the organic molecule according to claim 16 as a luminescent emitter and/or a host,
an emitter and/or a host material, the emitter differing from the organic molecule, and
optionally, a dye and/or a solvent.

27. An optoelectronic device, comprising the composition according to claim 26, wherein the optoelectronic device is selected from the group consisting of organic light-emitting diodes (OLED), light-emitting electrochemical cells, OLED-sensors, organic diodes, organic solar cells, organic transistors, organic field-effect transistors, organic lasers, down-conversion elements, and combinations thereof.

28. The optoelectronic device according to claim 24, comprising:
a substrate;
an anode, and
a cathode, the anode or the cathode being on the substrate; and
a light-emitting layer between the anode and the cathode and comprising the organic molecule.

29. A method for producing an optoelectronic device, the method comprising depositing the organic molecule according to claim 16 by a vacuum evaporation method and/or a solution deposition method.

30. A method for producing an optoelectronic device, the method comprising depositing the composition according to claim 26 by a vacuum evaporation method and/or a solution deposition method.

31. The optoelectronic device according to claim 27, comprising:
a substrate;
an anode, and
a cathode, the anode or the cathode being on the substrate; and
a light-emitting layer between the anode and the cathode and comprising the composition.

32. An optoelectronic device, comprising a layer formed from the composition according to claim 26, wherein the optoelectronic device is selected from the group consisting of organic light-emitting diodes (OLED), light-emitting electrochemical cells, OLED-sensors, organic diodes, organic solar cells, organic transistors, organic field-effect transistors, organic lasers, down-conversion elements, and combinations thereof.

33. The optoelectronic device according to claim 32, comprising:
a substrate;
an anode, and
a cathode, the anode or the cathode being on the substrate; and
a light-emitting layer between the anode and the cathode and comprising the layer formed from the composition.
